(19) United States
(12) Patent Application Publication
(10) Pub. No.: US 2025/0379549 A1
(43) Pub. Date: Dec. 11, 2025

(54) EFFICIENCY ENHANCED POWER AMPLIFIER SYSTEM

(71) Applicant: Qorvo US, Inc., Greensboro, NC (US)

(72) Inventors: Charles Forrest Campbell, Dallas, TX (US); Srinath Mathur Ramaswamy, Murphy, TX (US)

(21) Appl. No.: 19/194,816

(22) Filed: Apr. 30, 2025

Related U.S. Application Data
(60) Provisional application No. 63/657,331, filed on Jun. 7, 2024.
(60) Provisional application No. 63/688,998, filed on Aug. 30, 2024.

(51) Int. Cl. H03F 3/24

(52) U.S. Cl. CPC H03F 3/245; H03F 2200/451

(57) ABSTRACT

Embodiments of a reconfigurable power amplifier are disclosed. In some embodiments, a reconfigurable quadrature coupler includes a first amplifier, a second amplifier, an input-side quadrature coupler, and an output-side quadrature coupler. The first amplifier has a first amplifier input terminal and a first amplifier output terminal. The second amplifier has a second amplifier input terminal and a second amplifier output terminal. The input-side reconfigurable quadrature coupler is coupled to the first input terminal and the second input terminal, wherein the input-side reconfigurable quadrature coupler has unequal coupling coefficients. The output-side reconfigurable quadrature coupler is coupled to second amplifier input terminal and a second amplifier output terminal, the output-side reconfigurable quadrature coupler has an inverted configuration with respect to the input-side reconfigurable quadrature coupler. In this manner, the amplifiers can operate at different power levels without having to adjust a gain of amplifiers.

### RELATED APPLICATIONS

This application claims the benefit of provisional patent application Ser. No. 63/688,998, filed Aug. 30, 2024, and claims the benefit of provisional patent application Ser. No. 63/657,331, filed Jun. 7, 2024, the disclosures of which are hereby incorporated herein by reference in their entireties.

### FIELD OF THE DISCLOSURE

This disclosure relates to power amplifiers and methods of designing the same.

### BACKGROUND

Organizations like the 3^{rd} Generation Partnership Project (3GPP) are working to enhance and bridge the infrastructure gap by defining and developing new standards, such as the 5G New Radio (NR). This opens up higher frequencies, including millimeter Wave (mm-Wave) bands, for terrestrial and satellite communication applications. The mm-Wave bands offer a significantly larger useful spectrum and regulators are more willing to allocate them to 5G operators. Additionally, the mm-Wave range provides wider contiguous spectrum blocks that can accommodate single 5G carriers with larger frequency bandwidth, resulting in less loss of spectral efficiency from overheads.

3GPP Release 15 specifies two frequency bands: FR1 and FR2. FR1 is limited to frequencies below 6 GHz, while FR2 targets the K-Ka Bands (24.25-40 GHz). This broader spectrum availability necessitates advancements in component design to leverage the larger contiguous spectrum, including wide-band, high-frequency, and high-efficiency transmission (TX) and reception (RX) paths. The power amplifier (PA) subsystem is critical, as it determines the overall energy efficiency and thermal considerations of a radio transceiver system. The PA subsystem must maintain good power-added efficiency (PAE) at high, medium, and low output power levels. The lower available gain of semiconductor devices and higher transmission losses in these frequency bands means that managing energy efficiency and thermal management are essential for successful deployment.

The waveforms used in the 5G standard also play a crucial role in determining energy efficiency. Orthogonal Frequency-Division Multiplexing (OFDM) is a leading modulation type in modern telecommunications. The 5G waveforms are based on cyclic prefix OFDM (CP-OFDM) for both downlink and uplink, with the uplink optionally using Discrete Fourier Transform-Spread-OFDM (DFT-S-OFDM). DFT-S-OFDM offers a lower peak-to-average power ratio (PAPR) compared to CP-OFDM, but at these frequencies, the power back-off required to maintain sufficient linearity is still substantial. OFDM has a high PAPR; for instance, the back-off requirements for 64 Quadrature Amplitude Modulation (QAM) OFDM are around 10 decibels (dB) for a 0.001 probability of occurrence. This means that, for most signal transmission times, the PA will be backed off from the saturated output power point by 10 dB to minimize out-of-band spurious emissions and/or adjacent channel power ratio (ACPR), leading to a significant loss of efficiency.

### SUMMARY

Embodiment 1: A reconfigurable power amplifier including: a first amplifier having a first amplifier input terminal and a first amplifier output terminal; a second amplifier having a second amplifier input terminal and a second amplifier output terminal; a first input-side reconfigurable quadrature coupler coupled to the first amplifier input terminal and the second amplifier input terminal, wherein the first input-side reconfigurable quadrature coupler has unequal coupling coefficients; and a first output-side reconfigurable quadrature coupler coupled to the second amplifier input terminal and the second amplifier output terminal, the first output-side reconfigurable quadrature coupler having an inverted configuration with respect to the first input-side reconfigurable quadrature coupler.

Embodiment 2: The reconfigurable power amplifier of embodiment 1, wherein: the first input-side reconfigurable quadrature coupler includes a first signal port, a first through port, a first coupled port, and a first isolated port; the first through port is coupled to the first amplifier input terminal of the first amplifier; the first coupled port is coupled to the second amplifier input terminal of the second amplifier; the first input-side reconfigurable quadrature coupler includes a first through port coupling coefficient between the first signal port and the first through port and a first coupled port coupling coefficient between the first signal port and the first coupled port; and the first input-side reconfigurable quadrature coupler has the unequal coupling coefficients as a result of the first through port coupling coefficient and the first coupled port coupling coefficient being unequal.

Embodiment 3: The reconfigurable power amplifier of embodiment 2, wherein: the first output-side reconfigurable quadrature coupler includes a second signal port, a second through port, a second coupled port, and a second isolated port; the first output-side reconfigurable quadrature coupler having a second through port coupling coefficient between the second signal port and the second through port and a second coupled port coupling coefficient between the second signal port and the second coupled port; and the first output-side reconfigurable quadrature coupler has the inverted configuration with respect to the first input-side reconfigurable quadrature coupler by: the second through port being coupled to the second amplifier output terminal of the second amplifier; the second coupled port being coupled to the first amplifier output terminal of the first amplifier; the second though port coupling coefficient of the first output-side reconfigurable quadrature coupler being substantially equal to the first coupled port coupling coefficient of the first input-side reconfigurable quadrature coupler; and the second coupled port coupling coefficient of the first output-side reconfigurable quadrature coupler being substantially equal to the first through port coupling coefficient of the first input-side reconfigurable quadrature coupler.

Embodiment 4: The reconfigurable power amplifier of embodiment 1, further including: a 2N-1 number of input-side reconfigurable quadrature couplers including the first input-side reconfigurable quadrature, the 2^{N}−1 number of input-side reconfigurable quadrature couplers being connected in a first tree structure with the first input-side reconfigurable quadrature coupler being at a base of the first tree structure and a root of the first tree structure being one of the input-side reconfigurable quadrature couplers having a main input terminal; a 2^{N}−1 number of output-side reconfigurable quadrature couplers including the first output-side reconfigurable quadrature, the 2^{N}−1 number of output-side reconfigurable quadrature couplers being connected in a second tree structure with the second output-side reconfigurable quadrature coupler being at a base of the second tree structure and a root of the second tree structure is one of the output-side reconfigurable quadrature couplers having a main output terminal; a 2^{N} number of amplifiers including the first amplifier and the second amplifier, the 2^{N} number of amplifiers being divided into amplifier pairs, each of the amplifier pairs having amplifier input terminals coupled to a different one of the 2^{N}−1 number of input-side reconfigurable quadrature couplers at the base of the first tree structure and having amplifier output terminals coupled to a different one of the 2^{N}−1 number of output-side reconfigurable quadrature couplers at the base of the second tree structure; at least some of the 2^{N}−1 number of input-side reconfigurable quadrature couplers having the unequal coupling coefficients; each of the 2^{N}−1 number of output-side reconfigurable quadrature couplers having the inverted configuration with respect to the first input-side reconfigurable quadrature coupler that has a position in the first tree structure that corresponds to a position of the first output-side reconfigurable quadrature coupler in the second tree structure; and wherein N is an integer equal to 2 or greater.

Embodiment 5: The reconfigurable power amplifier of embodiment 4, wherein an amplifier of the 2^{N} number of amplifiers is set to a same gain when the amplifier is activated.

Embodiment 6: The reconfigurable power amplifier of embodiment 5, wherein each of the 2^{N}−1 number of input-side reconfigurable quadrature couplers are configurable in a through mode or a quadrature more and each of the 2^{N}−1 number of output-side reconfigurable quadrature couplers are reconfigurable to operate in a coupled mode or the quadrature mode.

Embodiment 7: The reconfigurable power amplifier of embodiment 6, further including a control circuit, wherein the control circuit is configured to: operate in accordance with a deactivation plan having different activation states, wherein, in each activation state, different combinations of the 2^{N} number of amplifiers are activated and deactivated, wherein an inverted mode of the quadrature mode is the quadrature mode, an inverted mode of the coupled mode is the through mode, and an inverted mode of the through mode is the coupled mode; in each activation state of the different activation states, setting each of the 2^{N}−1 number of input-side reconfigurable quadrature couplers in either the quadrature mode, the through mode, or the coupled mode; and in each activation state of the different activation states, set each of the 2^{N}−1 number of output-side reconfigurable quadrature couplers in the inverted mode with respect to the 2^{N}−1 number of input-side reconfigurable quadrature coupler that has the position in the first tree structure that corresponds to the position of the 2^{N}−1 number of output-side reconfigurable quadrature couplers in the second tree structure.

Embodiment 8: The reconfigurable power amplifier of embodiment 7, wherein, in each of the different activation states, each of the 2^{N}−1 number of input-side reconfigurable quadrature couplers is set to either the quadrature mode, the through mode, or the coupled mode such that portions of an input signal received at the main input port are routed only to amplifiers of the 2^{N} number of amplifiers that are activated in one of the different activation states.

Embodiment 9: The reconfigurable power amplifier of embodiment 1, wherein the first amplifier and the second amplifier are set to a same gain when the first amplifier and the second amplifier are activated.

Embodiment 10: The reconfigurable power amplifier of embodiment 9, wherein the first input-side reconfigurable quadrature coupler and the first output-side reconfigurable quadrature coupler are reconfigurable to operate in a quadrature mode, a through mode, and a coupled mode.

Embodiment 11: A method of designing a reconfigurable power amplifier including pairs of amplifiers, input-side reconfigurable quadrature couplers in a first tree structure, and output-side reconfigurable quadrature couplers in a second tree structure, the method including: selecting a deactivation plan for the reconfigurable power amplifier; selecting decibel power steps for the reconfigurable power amplifier; deriving the real power levels of each of the amplifiers based on the deactivation plan and the decibel power steps; and deriving coupling coefficients for the input-side reconfigurable quadrature couplers and the output-side reconfigurable quadrature couplers based on the real power levels.

Embodiment 12: The method of embodiment 11, wherein the real power levels are derived at a 1 decibel compression point.

Embodiment 13: The method of embodiment 11, wherein each of the amplifiers are designed to be set to a same gain when the amplifier is activated.

Embodiment 14: A user element including a reconfigurable power amplifier, the reconfigurable power amplifier including: a first amplifier having a first amplifier input terminal and a first amplifier output terminal; a second amplifier having a second amplifier input terminal and a second amplifier output terminal; a first input-side reconfigurable quadrature coupler coupled to the first amplifier input terminal and the second amplifier input terminal, wherein the first input-side reconfigurable quadrature coupler has unequal coupling coefficients; and a first output-side reconfigurable quadrature coupler coupled to the second amplifier input terminal and the second amplifier output terminal, the first output-side reconfigurable quadrature coupler having an inverted configuration with respect to the first input-side reconfigurable quadrature coupler.

Embodiment 15: The user element of embodiment 14, wherein: the first output-side reconfigurable quadrature coupler includes a second signal port, a second through port, a second coupled port, and a second isolated port; the first output-side reconfigurable quadrature coupler has a second through port coupling coefficient between the second signal port and the second through port and a second coupled port coupling coefficient between the second signal port and the second coupled port; and the first output-side reconfigurable quadrature coupler has the inverted configuration with respect to the first input-side reconfigurable quadrature coupler by: the second through port being coupled to the second amplifier output terminal of the second amplifier; the second coupled port being coupled to the first amplifier output terminal of the first amplifier; the second though port coupling coefficient of the first output-side reconfigurable quadrature coupler being substantially equal to the first coupled port coupling coefficient of the first input-side reconfigurable quadrature coupler; and the second coupled port coupling coefficient of the first output-side reconfigurable quadrature coupler being substantially equal to the first through port coupling coefficient of the first input-side reconfigurable quadrature coupler.

Embodiment 16: The user element of embodiment 14, further including: a 2^{N}−1 number of input-side reconfigurable quadrature couplers including the first input-side reconfigurable quadrature coupler, the 2^{N}−1 number of input-side reconfigurable quadrature couplers being connected in a first tree structure with the first input-side reconfigurable quadrature coupler being at a base of the first tree structure and a root of the first tree structure being one of the 2^{N}−1 number of input-side reconfigurable quadrature couplers having a main input terminal; a 2^{N}−1 number of output-side reconfigurable quadrature couplers including the first output-side reconfigurable quadrature coupler, the 2^{N}−1 number of output-side reconfigurable quadrature couplers being connected in a second tree structure with the second output-side reconfigurable quadrature coupler being at a base of the second tree structure and a root of the second tree structure being one of the 2^{N}−1 number of output-side reconfigurable quadrature couplers having a main output terminal; a 2^{N} number of amplifiers including the first amplifier and the second amplifier, the 2^{N} number of amplifiers being divided into amplifier pairs, each of the amplifier pairs having amplifier input terminals coupled to a different one of the 2^{N}−1 number of input-side reconfigurable quadrature couplers at the base of the first tree structure and having amplifier output terminals coupled to a different one of the 2^{N}−1 number of output-side reconfigurable quadrature couplers at the base of the second tree structure; at least some of the 2^{N}−1 number of input-side reconfigurable quadrature couplers having the unequal coupling coefficients; each of the 2^{N}−1 number of output-side reconfigurable quadrature couplers having the inverted configuration with respect to the input-side reconfigurable quadrature coupler that has a position in the first tree structure that corresponds to a position of the output-side quadrature coupler in the second tree structure; and wherein N is and integer equal to 2 or greater.

Embodiment 17: The user element of embodiment 16, wherein each amplifier of the 2^{N} number of amplifiers is set to a same gain when the amplifier is activated.

Embodiment 18: The user element of embodiment 17, wherein each of the 2^{N}−1 number of input-side reconfigurable quadrature couplers are each configurable in a through mode or a quadrature mode and each of the 2^{N}−1 number of output-side reconfigurable quadrature couplers are reconfigurable to operate in a coupled mode or the quadrature mode.

Embodiment 19: The user element of embodiment 18, further including a control circuit, wherein the control circuit is configured to: operate in accordance with a deactivation plan having different activation states, wherein, in each activation state, different combinations of the 2^{N} number of amplifiers are activated and deactivated, wherein an inverted mode of the quadrature mode is the quadrature mode, an inverted mode of the coupled mode is the through mode, and an inverted mode of the through mode is the coupled mode; in each activation state of the different activation states, setting each of the 2^{N}−1 number of input-side reconfigurable quadrature couplers in either the quadrature mode, the through mode, or the coupled mode; and in each activation state of the different activation states, set each of the 2^{N}−1 number of output-side reconfigurable quadrature couplers in the inverted mode with respect to the 2^{N}−1 number of input-side reconfigurable quadrature couplers that has the position in the first tree structure that corresponds to the position of the 2^{N}−1 number of output-side reconfigurable quadrature couplers in the second tree structure.

Embodiment 20: The user element of embodiment 19, wherein, in each of the different activation states, each of the 2^{N}−1 number of input-side reconfigurable quadrature couplers is set to either the quadrature mode or the through mode such that portions of an input signal received at the main input port are routed only to the amplifiers that are activated in an activation state.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A illustrates a simplified diagram of a three-mode reconfigurable quadrature coupler that is structured in accordance with the present disclosure, in accordance with some embodiments;

FIG. 1B illustrates the reconfigurable quadrature coupler of FIG. 1A in a through mode with a through mode signal path indicated by a large arrow, in accordance with some embodiments;

FIG. 1C illustrates the reconfigurable quadrature coupler of FIG. 1A in a coupled mode with a coupled mode signal path indicated by a large arrow, in accordance with some embodiments;

FIG. 1D illustrates the reconfigurable quadrature coupler of FIG. 1A in addition to coupling coefficients associated with the ports of the reconfigurable quadrature coupler, in accordance with some embodiments;

FIG. 2 illustrates an exemplary embodiment of a generalized 2^{N}-level power reconfigurable power amplifier, which is a schematic of a 2^{N}-level power reconfigurable power amplifier, in accordance with some embodiments;

FIG. 3A illustrates a four-level power version of a reconfigurable power amplifier, in accordance with some embodiments;

FIG. 3B illustrates a deactivation plan for the reconfigurable power amplifier of FIG. 3A in order to design the reconfigurable power amplifier to achieve described output power levels, in accordance with some embodiments;

FIGS. 4A-4D illustrate the reconfigurable power amplifier of FIG. 3A operating in accordance with the configuration described in FIG. 3A and FIG. 3B in three different power modes, in accordance with some embodiments;

FIG. 5A and FIG. 5B illustrate simulation results of a computer model of the reconfigurable power amplifier shown in FIG. 3A, in accordance with some embodiments;

FIG. 6A and FIG. 6B illustrate a reconfigurable power amplifier along with additional details regarding a control circuit included in the reconfigurable power amplifier, in accordance with some embodiments;

FIG. 7 illustrates a reconfigurable power amplifier along with additional details regarding a control circuit included in the reconfigurable power amplifier, in accordance with some embodiments;

FIG. 8 illustrates average power tracking of frame-based signals, in accordance with some embodiments;

FIG. 9 is a flow diagram of a method of designing a reconfigurable power amplifier, in accordance with some embodiments; and

FIG. 10 illustrates a user element in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

The term “equal” or the symbol “=” in the specification of this disclosure is also to carry the meaning “substantially equal.” To be “substantially equal” refers to the capabilities of the reconfigurable power amplifier and, specifically, the reconfigurable quadrature couplers described herein. No technology that splits and combines signals is capable of performing signal splitting and signal combinations in a manner that is 100% and perfectly equal (i.e., equal in an ideal sense). Thus, the term “substantially equal” refers to providing 90% combining efficiency or better. 90% combining efficiency would result in about 0.5 decibels (dB) of combining loss, a number typically budgeted into output power specifications (e.g., if one amplifier's output is at 750 milliwatts (mW) and a second amplifier's output is at 250 mW, a 90% combining efficiency would result in 900 mW leaving the output coupler).

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

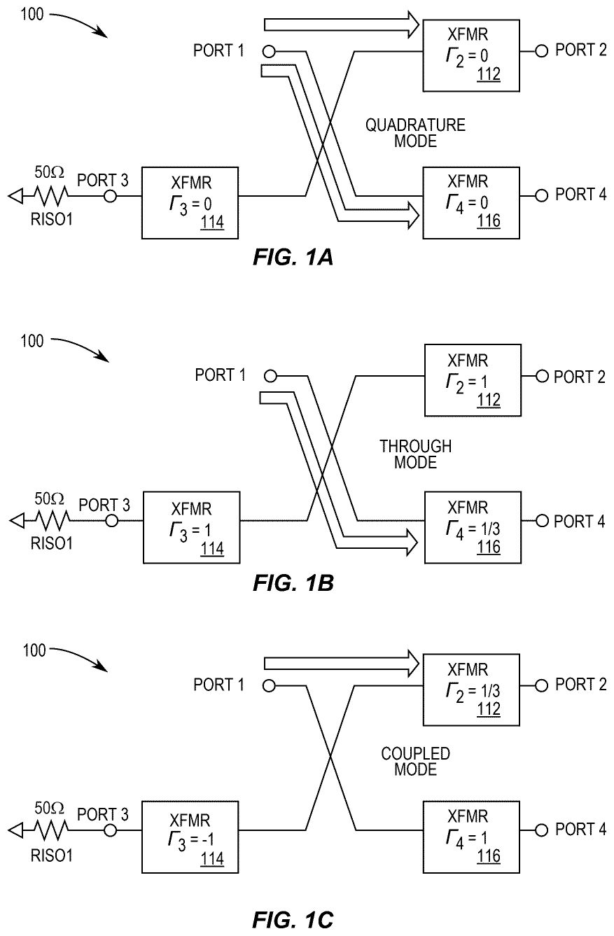

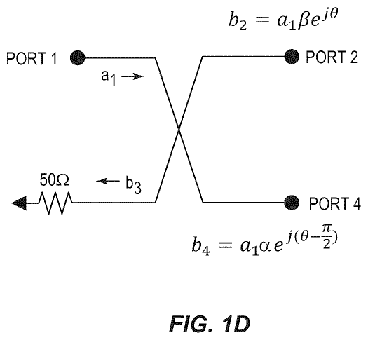

FIG. 1A illustrates a simplified diagram of a three-mode reconfigurable quadrature coupler 100 that is structured in accordance with the present disclosure, in accordance with some embodiments.

The reconfigurable quadrature coupler 100 includes a first port (PORT 1) and a second port (PORT 2) coupled to a PORT 2 transformer 112. The PORT 2 transformer 112 is configured to have a selectable second port reflection coefficient Γ². The reconfigurable quadrature coupler 100 further includes a third port (PORT 3) connected to a PORT 3 transformer 114. The PORT 3 transformer 114 is configured to have a selectable third port reflection coefficient Γ³. An isolation resistor RISO1 may be connected between PORT 3 and ground. A fourth port (PORT 4) is connected to a PORT 4 transformer 116. The PORT 4 transformer 116 is configured to have a selectable fourth port reflection coefficient Γ₄. In exemplary embodiments, such as those depicted in FIG. 1A, the reconfigurable quadrature coupler 100 is of a Lange coupler type. However, the reconfigurable quadrature coupler 100 may be any type of quadrature coupler including a rat race coupler, coupled transmission lines, or any type of quadrature coupler configured to realize a quadrature coupler function.

FIG. 1A depicts the reconfigurable quadrature coupler 100 in a quadrature mode with a first quadrature signal path indicated by a first large arrow between PORT 1 and PORT 2, along with a second quadrature signal path indicated by a second large arrow between PORT 1 and PORT 4. A phase relationship between through and coupled modes is the same as what occurs for a normal quadrature operation with a through path being −90° phase shifted from a coupled path. This is a key property for this circuit, as the couplers can be reconfigured in a balanced amplifier architecture without altering the natural phase relationships.

In this embodiment, PORT 1 is a signal port. PORT 1 (i.e., the signal port) serves as an input port or an output port of the reconfigurable quadrature coupler 100. PORT 2 is a coupled port. The coupled port PORT 2 has a phase shift of θ degrees with respect to the signal port PORT 1. PORT 3 is an isolated port and ideally receives or transmits no power to the signal port (i.e., PORT 1). However, in practical embodiments, a small amount of power may leak to the isolated port (i.e., PORT 3). Finally, PORT 4 is a through port. The signal port PORT 1 is configured to receive or transmit power to the through port (i.e., PORT 4) with a 90° phase shift (e.g., θ-90 degrees). In some embodiments, the coupler 100 is about a quarter wave (90 deg) long thus the input signal at the signal port PORT 1 travels this 90 deg of length to get to the thru port PORT 4. In passive networks, phase decreases, hence −θ−90 degrees phase of additional shift from PORT 1 to PORT 4. Reflections off of the loads connected to PORT 2 and PORT 4 are directed to PORT 3. In response to PORT 2 and PORT 4 being perfectly loaded, no signal is provided at PORT 3.

FIG. 1B illustrates the reconfigurable quadrature coupler 100 of FIG. 1A in the through mode with a through mode signal path indicated by a large arrow between PORT 1 and PORT 4, in accordance with some embodiments.

First, consider that, in the through mode of operation, all input power of PORT 1 is directed to PORT 4. For this to occur, there can be no power dissipation in the PORT 2 transformer 112 and the PORT 3 transformer 114. Terminating impedances associated with PORT 2 and PORT 3 must produce unity magnitude reflection coefficients so that all energy is reflected back into the reconfigurable quadrature coupler 100.

FIG. 1C illustrates the reconfigurable quadrature coupler 100 of FIG. 1A in the coupled mode with a coupled mode signal path indicated by a large arrow between PORT 1 and PORT 2, in accordance with some embodiments.

For lossless power transfer from PORT 1 to PORT 2 and PORT 1 to PORT 4, PORT 1 must be matched such that the selectable first port reflection coefficient Γ₁=0. A required value for the selectable fourth port reflection coefficient Γ₄ is set by a reconfiguration of the fourth port transformer 116 for operation of the through mode. The reflection coefficient Γ₁=0 is a consequence of properly set transformer reflection coefficients Γ₂, Γ₃, and Γ₄. The reflection coefficient Γ₁=0 is true under ideal circumstances. In practical circumstances, the reflection coefficient Γ₁ is not equal exactly to zero.

Reconfigurable power amplifiers of the present disclosure each utilize N nested pairs of reconfigurable Lange couplers. Unlike related-art designs, the reconfigurable quadrature coupler 100 can be reconfigured to operate in one of three modes: the quadrature mode, the through mode, and the coupled mode. The quadrature mode equally splits input signals into quadrature outputs and requires a 500 termination on all four ports (PORT 1 through PORT 4) of the reconfigurable quadrature coupler 100. By reconfiguring the terminating impedances connected to three of the coupled ports, all the power can be directed to PORT 4 or to PORT 2. FIGS. 1A-1C each show one of many possible combinations of the terminating impedances. For example, magnitudes are unity or ⅓ but, for the through mode, the phases (phase here describes the phase of the tuner reflection coefficients, which is not the same as the phase differences between the ports) must satisfy:

$${e}^{j {ϕ}_{2}} - \vert {Γ}_{4} \vert {e}^{j {ϕ}_{4}} - 2 \vert {Γ}_{4} \vert {e}^{j ( {ϕ}_{2} + {ϕ}_{3} + {ϕ}_{4} )} = 0$$

and, for the coupled mode, the phases must satisfy:

$$\vert {Γ}_{2} \vert {e}^{j {ϕ}_{2}} - {e}^{j {ϕ}_{4}} - 2 \vert {Γ}_{2} \vert {e}^{j ( {ϕ}_{2} + {ϕ}_{3} + {ϕ}_{4} )} = 0$$

The reflection coefficients equal 1 and −1 in the 0° and 180° cases, respectively. There is an infinite number of other combinations that will produce identical results.

The through and coupled modes are quadrature to each other, which enables power reconfigurable amplifier architectures using one or more pairs of reconfigurable quadrature couplers 100 of the Lange coupler type.

FIG. 1D illustrates the reconfigurable quadrature coupler 100 of FIG. 1A in addition to coupling coefficients associated with the ports (PORT 1, PORT 2, PORT 3, PORT 4) of the reconfigurable quadrature coupler 100, in accordance with some embodiments.

A signal a₁ is located at PORT 1. A signal b₂ results from the signal a₁ at PORT 2. A signal b₃ results from the signal a₁ at PORT 3. A signal b₄ results from the signal a₁ at PORT 4. A coupled port coupling coefficient β is between the coupled port (i.e., PORT 2) and the signal port (i.e., PORT 1). A through port coupling coefficient α is between the through port (i.e., PORT 4) and the signal port (i.e., PORT 1).

The reconfigurable quadrature coupler 100 may be constructed so that the power transfer between PORT 1 and PORT 2 is unequal to the power transfer between PORT 1 and PORT 4. In other words, the through port coupling coefficient α and the coupled port coupling coefficient β are set such that an unequal amount of power is transferred between PORT 1 and PORT 2 and PORT 1 and PORT 4.

An angle θ is related to a phase of the signal and can be set to zero. Assume the signal splits into output powers P₂₁ and P₄₁. A decibel power split that is realized by a coupler is then equal to:

$${P}_{21} ( dBm ) - {P}_{41} ( dBm ) = Δ ( dB )$$

where Δ can be positive or negative. For a 1 mW input, the power of the output port is related to the coupling coefficients α, β by:

$$\begin{matrix}{P}_{21} ( mW ) = {β}^{2} \\ {P}_{41} ( mW ) = {α}^{2} = 1 - {β}^{2}\end{matrix}$$

For the second equation above, the through port coupling coefficient α is related to the coupled port coupling coefficient β through energy conservation. These equations may be simultaneously solved for the coupled port coupling coefficient β in decibels:

$$β ( dB ) = 10 log ( {β}^{2} ) = Δ ( dB ) - 10 log ( 1 + {10}^{( \frac{Δ ( d B )}{10} )} )$$

The through port coupling coefficient α (in dB) will then be:

$$α ( dB ) = 10 log ( 1 - {β}^{2} ) = β ( dB ) - Δ ( dB ) = - 10 log ( 1 + 1 {0}^{Δ ( d B ) / 10} )$$

These equations can be utilized to design for a power split between PORT 1 and PORT 2 that is unequal to the power transfer between PORT 1 and PORT 4, as explained below.

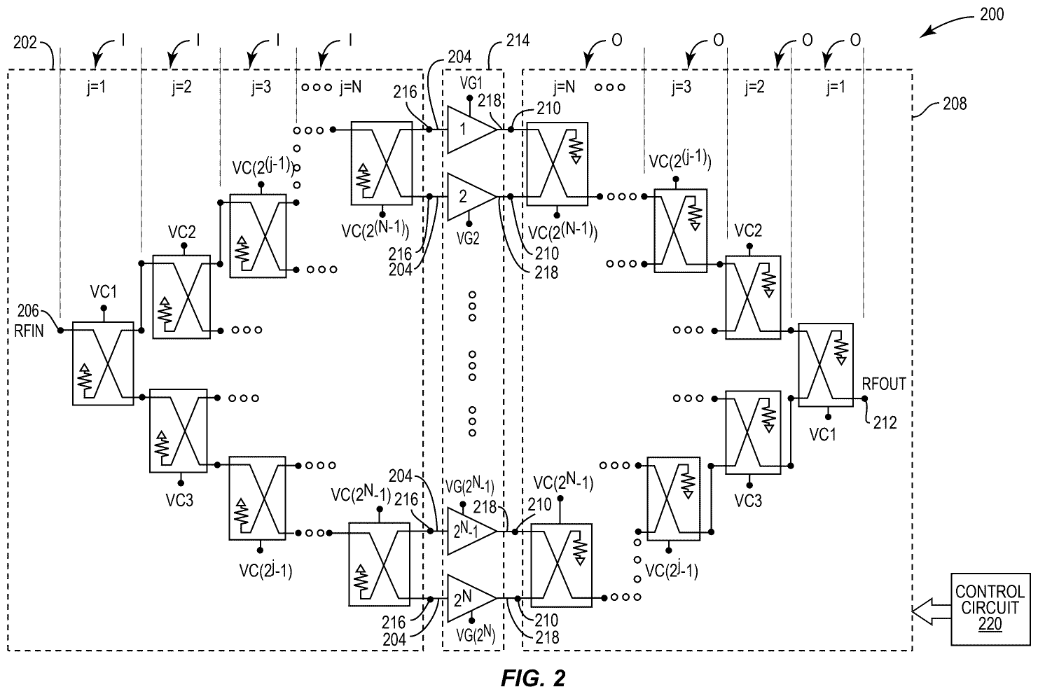

FIG. 2 illustrates an exemplary embodiment of a generalized 2^{N}-level power reconfigurable power amplifier, which is a schematic of a 2^{N}-level power reconfigurable power amplifier 200, in accordance with some embodiments.

The reconfigurable power amplifier 200 has a 2^{N}−1 number of input-side reconfigurable quadrature couplers 202 connected in a tree structure, wherein a 2^{N}−1 number of the input-side reconfigurable quadrature couplers 202 have coupler output terminals 204, and a root of the tree structure is one of the input-side reconfigurable quadrature couplers 202 having a main input terminal 206. Further included is a 2^{N}−1 number of output-side reconfigurable quadrature couplers 208 connected in a tree structure, wherein a 2^{N}−1 number of the output-side reconfigurable quadrature couplers 208 have coupler input terminals 210, and a root of the tree structure is one of the output-side reconfigurable quadrature couplers 208 having a main output terminal 212. The reconfigurable power amplifier 200 also includes a 2^{N} number of constituent amplifiers 214 divided into amplifier pairs having amplifier input terminals 216 connected to corresponding ones of the coupler output terminals 204 and having amplifier output terminals 218 coupled to corresponding ones of the coupler input terminals 210, wherein N is a natural counting number. Moreover, N is defined as an order of nesting of either the input-side reconfigurable quadrature couplers 202 or the output-side reconfigurable quadrature couplers 208. A number of realizable power levels is 2^{N} and a total range, in decibels, is P_{RNG}=Δ₁+Δ₂+Δ₃ (where P_{RNG} is the power range).

In FIG. 2, the reconfigurable power amplifier 200 is configured to provide any number of output power levels while maintaining efficiency as output power is backed off. Each of the amplifiers 214 are configured to receive a power supply voltage denoted by VG followed by an integer. For example, if the integer that follows the denotation VG is represented by an integer variable x, then x is an integer that varies between 1 to 2^{N}. Furthermore, the power supply voltage represented as VGx is received by the amplifier 214 labeled with the value of x. For example, if x is equal to 1, then the power supply voltage VG1 is received by a amplifier 1. In another example, if x is equal to 2^{N}−1, then the amplifier 2^{N}−1 receives the power supply voltage VG (2^{N}−1). However, while the power supply voltage levels of the power supply voltages VG are utilized to supply the amplifiers 214, the power supply voltages VG are not varied in order to achieve the various power levels. Instead, the power supply voltages VG are either supplied or not supplied in order to turn on or turn off the amplifier 214. In some embodiments, each constituent amplifier 214 of the 2^{N} number of constituent amplifiers 214 is set to the same gain when the constituent amplifier 214 is activated. For example, each of the constituent amplifiers 214 of the 2^{N} number of constituent amplifiers 214 may be set by the power supply voltage VG near saturation to maintain high power-added efficiency (PAE) when turned on. In this disclosure, efficiency is still maintained with output power adjustments, however, the difference is that the adjustments are discrete output power steps that can be made equal or unequal. This is accomplished with the reconfigurable quadrature couplers 202, 208 having unequal coupling coefficients. More specifically, each of the reconfigurable quadrature couplers 202, 208 have a through port coupling coefficient between the signal port and the through port. Furthermore, each of the reconfigurable quadrature couplers 202, 208 have a coupled port coupling coefficient between the signal port and the coupled port. For each of the reconfigurable quadrature couplers 202, 208, the through port coupling coefficient and the coupled port coupling coefficient are not equal. This means that the amount of power received by or transmitted from the through port and the coupled port is unequal. This is used to help distribute power through the reconfigurable power amplifier 200 in order to achieve the different power steps.

Additionally, the reconfigurable power amplifier 200 is operated in accordance with a deactivation plan. More specifically, the reconfigurable power amplifier 200 includes a control circuit 220. The control circuit 220 is configured to activate (i.e., turn on) and deactivate (i.e., turn off) different combinations of the 2^{N} number of constituent amplifiers 214 in order to achieve the different power levels. The control circuit 220 is configured to generate a control voltage. The voltages input into each of the input-side reconfigurable quadrature couplers 202, 208 are identified with an element identifier starting with “VC” and ending with a position identifier, where there are a total of 2^{N}−1 number of voltage inputs VC since there is a 2^{N}−1 number of input-side reconfigurable quadrature couplers 202 and a 2^{N}−1 number of output-side reconfigurable quadrature couplers 208.

Furthermore, each of the input-side reconfigurable quadrature couplers 202 are provided in a first tree structure and each of the output-side reconfigurable quadrature couplers 208 are provided in a second tree structure. In this embodiment, the first tree structure and the second tree structure are the same. The output-side reconfigurable quadrature couplers 208 have an inverted configuration with respect to the input-side reconfigurable quadrature couplers 202 that have a position in the first tree structure that corresponds to a position of the output-side reconfigurable quadrature couplers 208. For example, the first tree structure has multiple tree levels I and the second tree structure has multiple tree levels O. The letter “I” indicates that the tree levels are of the first tree structure and the letter “O” indicates that the tree levels are of the second tree structure. There is an N number of levels in the first tree structure and there is an N number of levels in the second tree structure. Thus, if j is an integer from 1 to N, the identifier I(j) refers to the j^{th} tree level of the input-side quadrature couplers 202 and the identifier O(j) refers to the j^{th} tree level of the output-side reconfigurable quadrature couplers 208. Thus, since the first tree structure has the same structure as the second tree structure, the tree levels in the first tree structure and the second tree structure with the same numeral j between the parenthesis are in the same tree level with respect to their respective tree structure. The root tree level of the first tree structure is the tree level I(1) while the base tree level of the first tree structure is the tree level I(N). This is because the main input port is the signal port of the input-side reconfigurable quadrature couplers 202 and the input-side reconfigurable quadrature couplers 202 in the tree level I(N) are directly connected to the amplifier input terminals 216 of the 2^{N} number of constituent amplifiers 214. The root tree level in the second tree structure is the tree level O(1) while the base tree level of the second tree structure is the tree level O(N). This is because the main output port is the signal port of the output-side reconfigurable quadrature couplers 208 and the output-side reconfigurable quadrature couplers 208 in the tree level O(N) are directly connected to the amplifier output terminals 218 of the 2^{N} number of constituent amplifiers 214.

In order for the position of the input-side reconfigurable quadrature couplers 202 to correspond to the position of the output-side reconfigurable quadrature couplers 208, the input-side reconfigurable quadrature couplers 202 have to be at the same tree level with respect to the first tree structure and the second tree structure and the input-side reconfigurable quadrature couplers 202 have to be directly or indirectly coupled to the amplifier input terminals 216 of the amplifier while the output-side reconfigurable quadrature couplers 208 are directly or indirectly coupled to the amplifier output terminals 218 of the same amplifiers. For example, the input-side reconfigurable quadrature couplers 202 at the tree level I(1) are at a corresponding position in the first tree structure as the output-side reconfigurable quadrature couplers 208 at the tree level O(1) because they are at the same level with respect to their tree structures and both are indirectly connected to all of the amplifiers. The input-side reconfigurable quadrature couplers 202 at the tree level I(N) are directly coupled to the amplifier input terminals 216 of amplifiers labeled 1 and 2 are at a corresponding position of the output-side reconfigurable quadrature couplers 208 at the tree level O(N) are coupled directly to the amplifier output terminals 218 of the amplifiers labeled 1 and 2. In this embodiment, the position of the input-side reconfigurable quadrature couplers 202 corresponds to the position of the output-side reconfigurable quadrature couplers 208 when the input-side reconfigurable quadrature couplers 202 and the output-side quadrature couplers 208 have the same position identifier (which, in this example, is next to the identifier VC, as explained above).

In FIG. 2, the though port coupling coefficient and the coupled port coupling coefficient of each of the input-side reconfigurable quadrature couplers 202 are inverted with respect to each of the output-side reconfigurable quadrature couplers 208 at a corresponding position. Thus, each of the input-side reconfigurable quadrature couplers 202 has a through port coupling coefficient that is equal to the coupled port coupling coefficient of the output-side reconfigurable quadrature couplers 208 having the same position identifier. Additionally, each of the input-side reconfigurable quadrature couplers 202 has a coupled port coupling coefficient that is equal to the through port coupling coefficient of the output-side reconfigurable quadrature couplers 208 having the same position identifier. Thus, for example, the input-side reconfigurable quadrature couplers 202 at the tree level (1) have a through port coupling coefficient that is equal to the coupled port coupling coefficient of the output-side reconfigurable quadrature couplers 208 at the tree level O(1). Furthermore, the input-side reconfigurable quadrature couplers 202 at the tree level I(1) have a coupled port coupling coefficient that is equal to the through port coupling coefficient of the output-side reconfigurable quadrature couplers 208 at the tree level O(1).

Additionally, the control circuit 220 is configured to set each of the output-side reconfigurable quadrature couplers 208 and the input-side reconfigurable quadrature couplers 202 at the corresponding positions in inverted modes. Thus, each of the input-side reconfigurable quadrature couplers 202 are in an inverted mode with respect to the output-side reconfigurable quadrature couplers 208 having the same position identifier. An inverted mode of the through port mode is the coupled mode and an inverted mode of the coupled mode is the through port mode. An inverted mode of the quadrature mode is the quadrature mode itself. Thus, for example, if the input-side reconfigurable quadrature couplers 202 that are in the tree level I(N) and are connected to the amplifier input terminals 216 of the amplifiers labeled 1, 2 are provided in the through port mode, then the output-side reconfigurable quadrature couplers 208 that are in the tree level O(N) and are connected to the amplifier output terminals 218 of the amplifiers labeled 1, 2 are placed in the coupled mode.

By having each of the output-side reconfigurable quadrature couplers 208 in inverted configurations with respect to each of the input-side reconfigurable quadrature couplers 202 at the corresponding positions, by setting the through port coupling coefficients and the coupled port coupling coefficients to particular unequal values, and by operating the reconfigurable power amplifier 200 with respect to the deactivation plan, the reconfigurable power amplifier 200 can be operated at different power levels without having to back each of the amplifiers to power supply levels not near saturation, thereby increasing the PAE of the reconfigurable power amplifier 200.

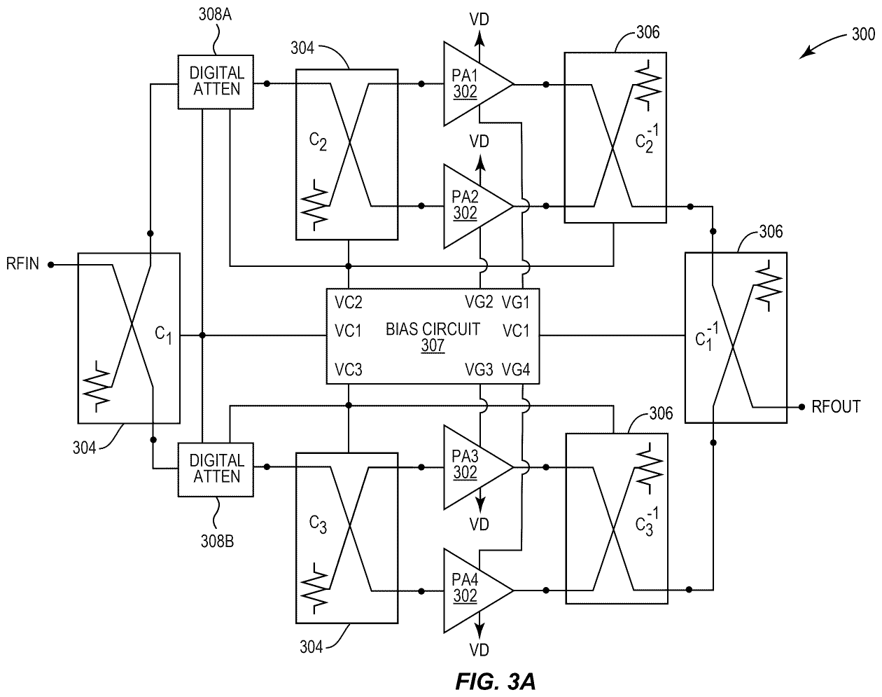

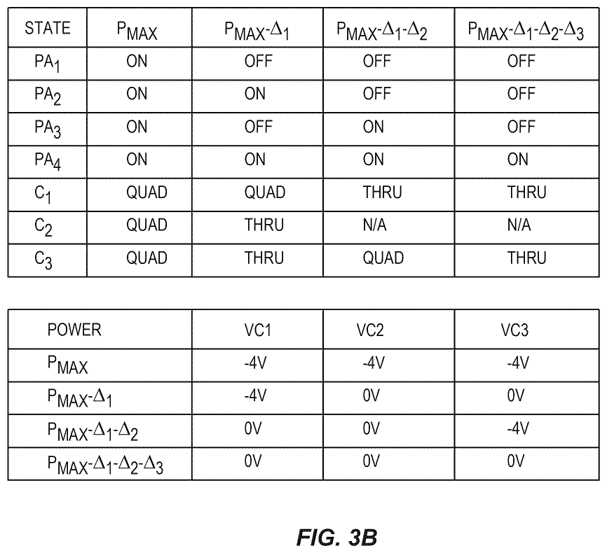

FIG. 3A illustrates a four-level power version of a reconfigurable power amplifier 300, in accordance with some embodiments.

The reconfigurable power amplifier 300 is a version of the reconfigurable power amplifier 200 shown in FIG. 2, where N=2.

Four power amplifiers 302 (PA₁, PA₂, PA₃, PA₄) are identical but have separate gate bias connections so that they can be individually deactivated. A bias circuit 307 provides a gate bias to the power amplifiers 302. The gate bias for the power amplifiers 302 is set to about −0.4 Volts (V) when operating and more negative than −1.2V when deactivated. Three input-side reconfigurable quadrature couplers 304 and three output-side reconfigurable quadrature couplers 306 each require independent control voltages (VC1, VC2, VC3) toggling between 0V and −4V. The bias circuit 307, can be designed to simultaneously deactivate the power amplifiers 302 as the power is reconfigured from one state to the next. The bias and control voltage levels listed here are consistent with gallium arsenide (GaAs) monolithic microwave integrated circuit (MMIC) technology. Other types of embodiments may use any other type of semiconductor technology. For example, other embodiments may correspond to to different voltage levels for other types of semiconductor technology including gallium nitride (GaN), silicon (Si) (e.g., complementary metal on oxide (CMOS), and silicon germanium (SiGe).

The input-side reconfigurable quadrature couplers 304 are labeled C₁, C₂, C₃, while the output-side reconfigurable quadrature couplers 306 are labeled with the same manner, except that the labels for the output-side reconfigurable quadrature couplers 306 are additionally labeled with a −1 to indicate the inverse configuration. Thus, the output-side reconfigurable quadrature coupler C₁⁻¹ is in a corresponding position, but in an inverted configuration with respect to the input-side reconfigurable quadrature coupler C₁. Output side reconfigurable quadrature coupler C₂⁻¹ is in a corresponding position, but in an inverted configuration with respect to the input-side reconfigurable quadrature coupler C₂. Output side reconfigurable quadrature coupler C₃⁻¹ is in a corresponding position, but in an inverted configuration with respect to the input-side reconfigurable quadrature coupler C₃.

Note that, with respect to the input-side reconfigurable quadrature couplers C₁, C₂, C₃ and the output-side reconfigurable quadrature couplers C₁⁻, C₂⁻¹, C₃⁻¹, the output-side reconfigurable quadrature couplers C₁⁻, C₂⁻¹, C₃⁻¹ are at a corresponding position as the input-side reconfigurable quadrature couplers C₁, C₂, C₃ and have an inverted relationship with respect to their coupled port and their through port. For example, the coupled port of the input-side reconfigurable quadrature coupler C₁ is coupled to the signal port of the input-side reconfigurable quadrature coupler C₂ and the through port of the input-side reconfigurable quadrature coupler C₁ is coupled to the signal port of the input-side reconfigurable quadrature coupler C₃. The coupled port of the output-side reconfigurable quadrature coupler C₁⁻¹ is coupled to the signal port of the output-side reconfigurable quadrature coupler C₃⁻¹ and the through port of the output-side reconfigurable quadrature coupler C₁⁻¹ is coupled to the signal port of the output-side reconfigurable quadrature coupler C₂⁻¹. The coupled port of the input-side reconfigurable quadrature coupler C₂ is coupled to an input port of the power amplifier PA₁ and the through port of the input-side reconfigurable quadrature coupler C₂ is coupled to an input port of the power amplifier PA₂. The coupled port of the output-side reconfigurable quadrature coupler C₂⁻¹ is coupled to an output port of the power amplifier PA₂ and the through port of the output-side reconfigurable quadrature coupler C₂⁻¹ is coupled to an output port of the power amplifier PA₁. The coupled port of the input-side reconfigurable quadrature coupler C₃ is coupled to an input port of the power amplifier PA₃ and the through port of the input-side reconfigurable quadrature coupler C₃ is coupled to an input port of the power amplifier PA₄. The coupled port of the output-side reconfigurable quadrature coupler C₃⁻¹ is coupled to an output port of the power amplifier PA₄ and the through port of the output-side reconfigurable quadrature coupler C₃⁻¹ is coupled to an output port of the power amplifier PA₃.

Optional digital trim step attenuators 308A, 308B are shown after the leftmost one of the input-side reconfigurable quadrature couplers 304 and are used to adjust for the small differences in loss between the quadrature, through, and coupled modes.

Attenuator bits are constructed of a small switch field effect transistor (FET) in series with a resistor to ground. To add attenuation, the small switch FET is biased ON by applying approximately 0V to a gate. For a no attenuation state, a voltage of less than −2V is applied to the gate of the small switch FET, placing it in an OFF state. Like power amplifier gate voltages, attenuator bias voltages can be generated from coupler control voltages.

The reconfigurable power amplifier 300 may be configured to produce different output power levels and maintain a correct radio frequency (RF) input drive to the power amplifiers 302 that are activated regardless of an output power setting. The approach taken in this embodiment can produce unequal output power level steps in dB (e.g., 0.00 dB, 1.25 dB, 3.01 dB, and 6.02 dB). In other embodiments, the output power level steps are equal and not determined by the designed steps. The techniques discussed herein can be used to define arbitrary power level steps with the restriction of coupler realizability (i.e., if the difference in the coupler split becomes too large, linewidth and spacing of traces that form the coupler may violate process design rules and, thus, the coupler may not be capable of being fabricated). In the following example, the bias circuit 307 is assumed to set the input-side reconfigurable quadrature couplers 304 to operate in either the quadrature or the through mode and the output-side reconfigurable quadrature couplers 306 are set to operate in either the quadrature or the coupled mode. The reconfigurable quadrature couplers 304, 306 are assumed to have an unequal power split and the power amplifiers 302 have different output power capabilities, which will be referenced to as the 1 dB compression point (P₁ dB). In other words, the input-side reconfigurable quadrature couplers 304 do not have an equal power split and operate in the quadrature mode or the through mode. The output-side reconfigurable quadrature couplers 306 do not have equal power splits and operate in the quadrature mode or the coupled mode. The digital trim step attenuators 308A, 308B adjust for small loss differences between the coupler modes. Individual amplifier input drives can be made independent of the power state with the correct deactivation plan.

The maximum output power level achievable by the reconfigurable power amplifier 300 is represented by the parameter Pₘₐₓ. The maximum output power level Pₘₐₓ is one of the output power levels achievable by the reconfigurable power amplifier 300. To determine the next highest achievable power level, the parameter Δ₁ is provided. More specifically, the next achievable power level is Pₘₐₓ−Δ₁. To determine the next achievable power level, the parameter Δ₂ is provided. More specifically, the next achievable power level is Pₘₐₓ−Δ₁−Δ₂. To determine the next achievable power level, the parameter Δ₃ is provided. More specifically, the next achievable power level is Pₘₐₓ-Δ₁-Δ₂-Δ₃.

FIG. 3B illustrates a deactivation plan for the reconfigurable power amplifier 300 of FIG. 3A in order to design the reconfigurable power amplifier 300 to achieve the described output power levels, in accordance with some embodiments.

The top table in FIG. 3B describes whether the power amplifier PA₁, PA₂, PA₃, or PA₄ is activated (i.e., ON) or deactivated (i.e., OFF) in each of the output power levels Pₘₐₓ, Pₘₐₓ−Δ₁, Pₘₐₓ-Δ₁-Δ₂, and Pₘₐₓ-Δ₁-Δ₂-Δ₃. The bottom table describes the control voltages provided to each of the reconfigurable quadrature couplers 304, 306 in each of the power levels Pₘₐₓ, Pₘₐₓ−Δ₁, P_{max-Δ1}−Δ₂, and Pₘₐₓ−Δ₁−Δ₂-Δ₃. Each of these power levels corresponds to a different power mode for operation of the reconfigurable power amplifier 300.

According to the deactivation plan, the individual power amplifier output levels at the P_{1dB} are:

$$\begin{matrix}{P}_{Max} = 10 log ( {PA}_{1} + P {A}_{2} + P {A}_{3} + P {A}_{4} ) \\ {P}_{Max} - {Δ}_{1} = 10 log ( {PA}_{2} + P {A}_{4} ) \\ {P}_{Max} - {Δ}_{1} - {Δ}_{2} = 10 log ( {PA}_{3} + P {A}_{4} ) \\ {P}_{Max} - {Δ}_{1} - {Δ}_{2} - {Δ}_{3} = 10 log ( {PA}_{4} )\end{matrix}$$

where the units are P_{Max} (dBm) and Δₓ(dB). The individual channel powers are converted to real power in Watts (W) and determined as:

$$\begin{matrix}P {A}_{4} ( W ) = {P}_{Max} ( W ) ( 1 {0}^{- ( {Δ}_{1} + {Δ}_{2} + {Δ}_{3} ) / 10} ) \\ {PA}_{3} ( W ) = {P}_{Max} ( W ) ( 1 {0}^{- ( {Δ}_{1} + {Δ}_{2} ) / 10} ) - P {A}_{4} ( W ) \\ {PA}_{2} ( W ) = {P}_{Max} ( W ) ( 1 {0}^{- \frac{{Δ}_{1}}{10}} ) - P {A}_{4} ( W ) \\ {PA}_{1} ( W ) = {P}_{Max} ( W ) - P {A}_{2} ( W ) - P {A}_{3} ( W ) - P {A}_{4} ( W )\end{matrix}$$

This works for arbitrary Δx provided that PA₂+PA₃+PA₄<P_{Max}. For example, Δ₁=Δ₂=1 dB and Δ₃=2 dB results in a negative value for the power amplifier PA₁ and would require a different deactivation plan to realize. Thus, if a negative power value is provided in order to achieve the power steps for one of the power amplifiers 302, the power steps are not realizable with the deactivation plan and a different deactivation plan has to be selected. The advantage of using equal power steps with this plan is that it guarantees the correct RF drive for each amplifier channel, independent of state. Unequal steps produce the correct RF drive for some of the power amplifiers 302 and states, but not always for all of them.

The next procedure is to determine the required coupling coefficients from the equations described above with respect to FIG. 1D. Note that the A for a particular coupler described above in FIG. 1D is related to the channel powers for that coupler and not related to the overall power step. This is best shown by example. Assume there is a 1 W 4-channel reconfigurable amplifier with an even power step of 2 dB. Therefore P_{Max}=1 W and Δ=Δ₁=Δ₂=Δ₃=2 dB. The individual channel amplifier at P_{1dB} is:

$$P {A}_{4} = 1000 ( mW ) ( 1 {0}^{- \frac{6}{10}} ) = 25 1.19 mW = 24. dBm$$

$$P {A}_{3} = 1000 ( mW ) ( 1 {0}^{- 4 / 10} ) - 25 1.19 ( mW ) = 1 46.92 mW = 21.67 dBm$$

$$P {A}_{2} = 1000 ( mW ) ( 1 {0}^{- \frac{2}{10}} ) - 25 1.19 ( mW ) = 3 79.77 mW = 25.8 dBm$$

$${PA}_{1} = 1000 mW - 3 79.77 mW - 1 46.92 mW - 2 51.19 mW = 222.12 mW = 23.47 dBm$$

The coupling coefficients for the reconfigurable quadrature couplers 304, 306 can now be calculated from the real power values of the power amplifiers 302. Note that all four power amplifiers 302 are at different power levels. The coupling coefficients for input-side reconfigurable quadrature couplers C₁, C₂, C₃ are derived from real power values for that particular input-side reconfigurable quadrature coupler C₁, C₂, C₃ and not from the overall reconfigurable power step. The power splits for the input-side reconfigurable quadrature couplers C₂, C₃ are:

$$\begin{matrix}Δ C 2 = P {A}_{1} - P {A}_{2} = 23.47 dBm - 25.8 dBm = - 2 \text{.33} dB \\ Δ C 3 = P {A}_{3} - P {A}_{4} = 21.67 dBm - 24. dBm = - 2.33 dB\end{matrix}$$

For the exterior input-side reconfigurable quadrature coupler C₁, the powers connected to each leg are summed before computing the split. The power split for the exterior input-side reconfigurable quadrature coupler C₁ is:

$$Δ {C}_{1} = 10 Log ( ( P {A}_{1} + P {A}_{2} ) / ( {PA}_{3} + P {A}_{4} ) = 27.8 dBm - 26. dBm = 1.8 dB$$

Note that the coupler splits are not equal to 2 dB. The various coupled and through port coefficients are:

$$\begin{matrix}{β}_{C 1} ( dB ) = 1.8 dB - 10 log ( 1 + 1 {0}^{1.8 d B / 10} ) = - 2 \text{.20} dB \\ {β}_{C 2} ( dB ) = - 2 \text{.33} dB - 10 log ( 1 + 1 {0}^{- 2.33 d B / 10} ) = - 4 \text{.33} dB \\ {β}_{C 3} ( dB ) = - 2 \text{.33} dB - 10 log ( 1 + 1 {0}^{- 2.33 d B / 10} ) = - 4 \text{.33} dB \\ {α}_{C 1} ( dB ) = {β}_{C 1} ( dB ) - {Δ}_{C 1} ( dB ) = - 2 \text{.20} dB - 1.8 dB = - 4 \text{.00} dB \\ {α}_{C 2} ( dB ) = {β}_{C 2} ( dB ) - {Δ}_{C 2} ( dB ) = - 4 \text{.33} dB + 2.33 dB = - 2 \text{.00} dB \\ {α}_{C 3} ( dB ) = {β}_{C 3} ( dB ) - {Δ}_{C 3} ( dB ) = - 4 \text{.33} dB + 2.33 dB = - 2 \text{.00} dB\end{matrix}$$

A designer can now take the calculated values and manufacture the reconfigurable power amplifier 300 to have the above-mentioned power levels. Note that the gain of the power amplifiers 302 does not have to be changed in order to provide the power levels. Instead, the gain of each of the power amplifiers 302 can remain constant as long as the particular power amplifier 302 is activated. Achieving the power levels is the result of activating and deactivating the power amplifiers 302 and the distribution of power by the reconfigurable quadrature couplers 304, 306, where the reconfigurable quadrature couplers 304, 306 provide an uneven power split in accordance with the calculated coupled and through port coefficients.

The architecture discussed FIG. 2 and FIG. 3A in this application uses quad/through mode on the input side and quad/coupled mode on the output side of the quadrature couplers. It was done this way because, in some embodiments, simulations of the circuitry indicate slightly lower insertion loss for the designs in FIG. 2 and FIG. 3A. Therefore, it is used on the output to improve power and efficiency. Everything described here is valid and could be executed with a quad/coupled mode on the input and quad/through mode on the output. These and other implementations would be apparent to one of ordinary skill in the art in light of this disclosure.

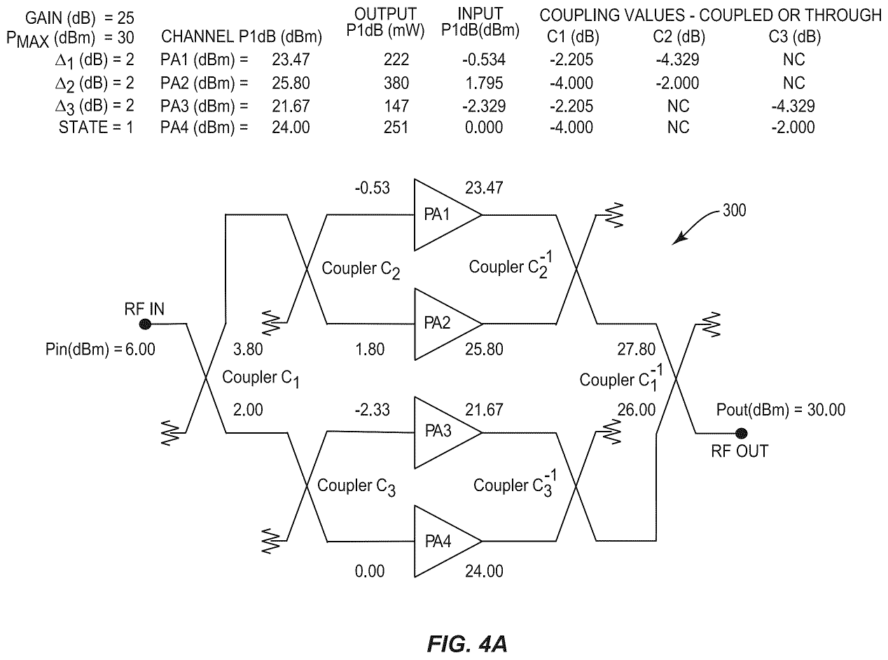

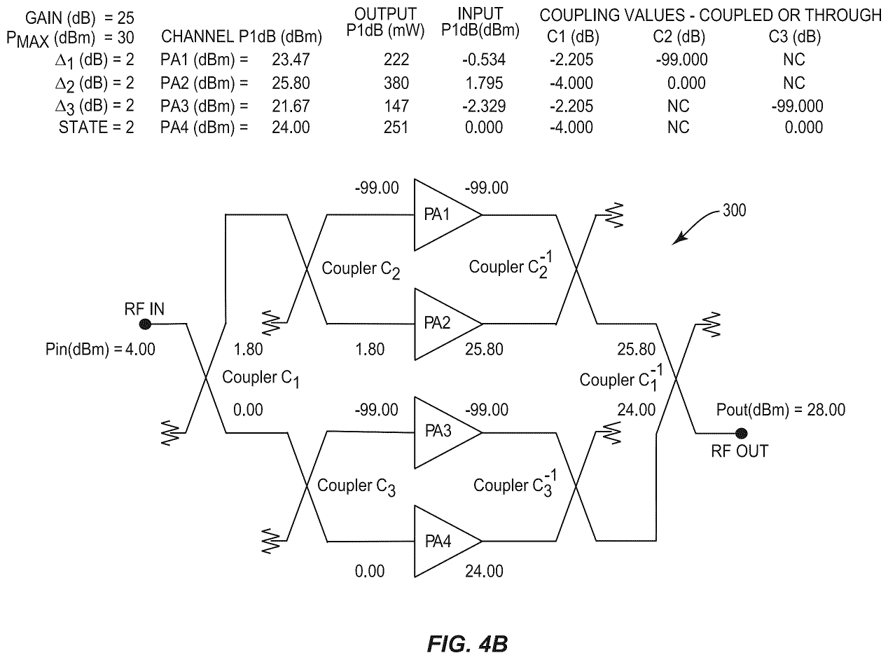

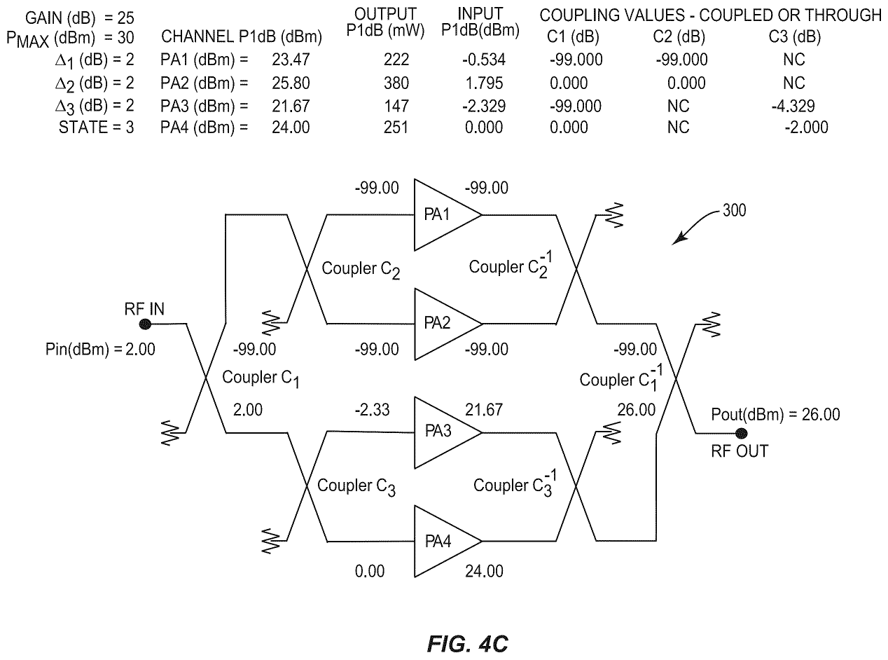

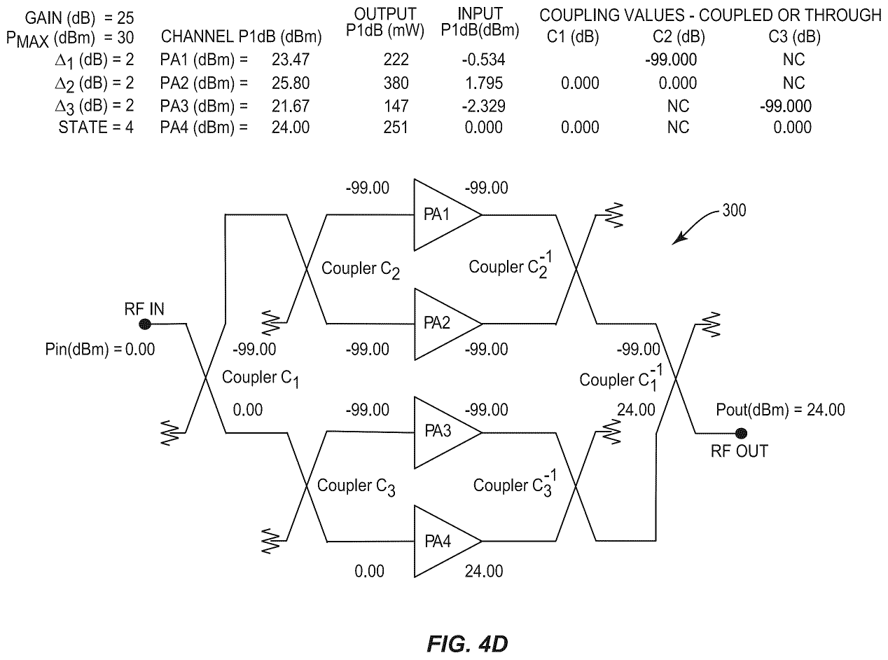

FIGS. 4A-4D illustrate the reconfigurable power amplifier 300 of FIG. 3A operating in accordance with the configuration described in FIG. 3A and FIG. 3B in four different power modes, in accordance with some embodiments.

FIG. 4A illustrates the reconfigurable power amplifier 300 in the highest power state along with a table describing the power and coupling coefficients for the reconfigurable power amplifier 300, in accordance with some embodiments. In the maximum power configuration, all four of the power amplifiers PA₁, PA₂, PA₃, PA₄ are activated, and all of the reconfigurable quadrature couplers C₁, C₂, C₃, C₁⁻, C₂⁻¹, C₃⁻¹ are operated in the quadrature mode. The table in FIG. 4A illustrates RF power levels in dBm at key points throughout the operation of the reconfigurable power amplifier 300. The reconfigurable power amplifier 300 exhibits a linear gain of 25 dB overall. When operating at 1 dB compression, the gain reduces to 24 dB, corresponding to an input power of 6 dBm (calculated as dBm output minus 24 dB gain). The table provides a visual representation of these power levels, which result from the structure of the reconfigurable power amplifier 300. The 6 dBm input power level simultaneously drives all four of the power amplifiers PA₁, PA₂, PA₃, PA₄ at P_{1dB} as well.

FIG. 4B illustrates the reconfigurable power amplifier 300 in the second highest power state along with a table describing the power and coupling coefficients for the reconfigurable power amplifier 300, in accordance with some embodiments. In this example, the power amplifiers PA₁, PA₃ are deactivated while the power amplifiers PA₂, PA₄ are activated. Thus, the power amplifiers PA₁, PA₃ are deactivated, as denoted by the “−99.00” label. In this example, the reconfigurable quadrature couplers C₁, C₁⁻¹ are in quadrature mode, the input-side reconfigurable quadrature couplers C₂, C₃ are in the through mode, and the output-side reconfigurable quadrature couplers C₂⁻¹, C₃⁻¹ are in the coupled mode. As expected, the output power is now 28 dBm and the input power is reduced by 2 dB to maintain a P_{1dB} compression level of the reconfigurable power amplifier 300. One can verify from the table in FIG. 4B that the active power amplifiers PA₂, PA₄ are still driven at P_{1dB}.

FIG. 4C illustrates the reconfigurable power amplifier 300 in the second lowest power state along with a table describing the power and coupling coefficients for the reconfigurable power amplifier 300, in accordance with some embodiments. In this power mode, the input-side reconfigurable quadrature coupler C₁ is set to the through mode and the output-side reconfigurable quadrature coupler C₁⁻¹ is set to the coupled mode. The power amplifiers PA₁, PA₂ are deactivated while the power amplifiers PA₃, PA₄ are activated. Since neither amplifier channel is connected to the input-side reconfigurable quadrature coupler C₂, it doesn't matter how the input-side reconfigurable quadrature C₂ is configured. Both the input-side reconfigurable quadrature coupler C₃ and the output-side reconfigurable quadrature coupler C₃⁻¹ are configured in the quadrature mode. The output power of the reconfigurable power amplifier 300 is now 26 dBm and the input power is reduced another 2 dB to maintain a P_{1dB} compression level for the reconfigurable power amplifier 300. Again, one can verify from the table that the active power amplifiers PA₃, PA₄ are driven at P_{1dB}.

FIG. 4D illustrates the reconfigurable power amplifier 300 in the lowest power state along with a table describing the power and coupling coefficients for the reconfigurable power amplifier 300, in accordance with some embodiments. In this power mode, only the power amplifier PA₄ is activated while the power amplifiers PA₁, PA₂, PA₃ are deactivated. Both of the input-side reconfigurable quadrature couplers C₁, C₃ are configured to the through mode while the output-side reconfigurable quadrature couplers C₁⁻, C₃⁻¹ are configured in the coupled mode. The mode of the reconfigurable quadrature couplers C₂, C₂⁻¹ is irrelevant since neither the power amplifier PA₁ nor the power amplifier PA₂ receive power from the reconfigurable quadrature couplers C₁, C₁⁻. Since the P_{1dB} for the power amplifier PA₄ is 24 dBm and the power amplifier PA₄ is the only one of the power amplifiers PA₁, PA₂, PA₃, PA₄ that is activated, the output level for the reconfigurable power amplifier 300 is also 24 dBm. Again, one can verify from the table in FIG. 4D that the active power amplifier PA₄ is driven at P_{1dB}. Thus, the power levels of the different power modes of the reconfigurable power amplifier 300 are 30 dBm, 28 dBm, 26 dBm, and 24 dBm. In this embodiment, the control voltages for the reconfigurable power amplifier 300 are shown in the bottom table of FIG. 3B and are 0V/−4V switch FET biases.

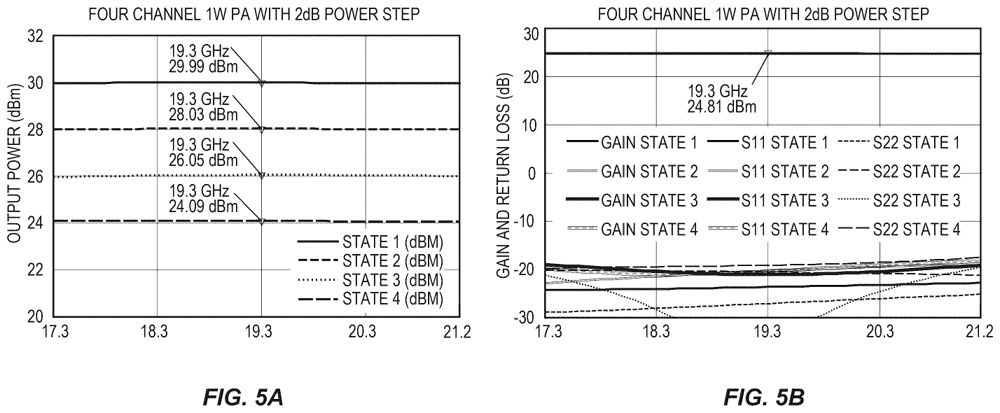

FIG. 5A and FIG. 5B illustrate simulation results of a computer model of the reconfigurable power amplifier 300 shown in FIG. 3A, in accordance with some embodiments.

Examples of the configurations of the reconfigurable quadrature couplers 304, 306 used for this computer model are shown in U.S. Pat. No. 11,539,108 B1 and U.S. Pat. No. 12,040,759 B2, both of which are incorporated by reference in their entirety. However, unlike what is described in those cited references, the reconfigurable quadrature couplers 304, 306 used herein have unequal coupling coefficients, as described above in the explanation of FIG. 3A and FIG. 3B. The reconfigurable quadrature couplers 304, 306 used for the computer model are closed form Lange coupler simulator models on 100 μm thick GaAs with 2 μm thick gold metallization. The transformers are modeled with ideal impedance tuners and the amplifiers are represented with an amplifier system model that includes compression.

FIG. 5A and FIG. 5B confirm that the reconfigurable power amplifier 300 works well for unequal split couplers. The couplers have a small amount of loss, so the input power had to be increased 0.5 dB to 6.5 dBm to get to P_{1dB} for the amplifiers PA₁, PA₂, PA₃, PA₄. Other than the input power adjustment, all aspects of the amplifier work as expected. The power A and state to state P_{1dB} drive levels are as designed. Good return loss was observed state to state with no additional matching elements. The gain is consistent state to state and is reduced slightly due to coupler loss.

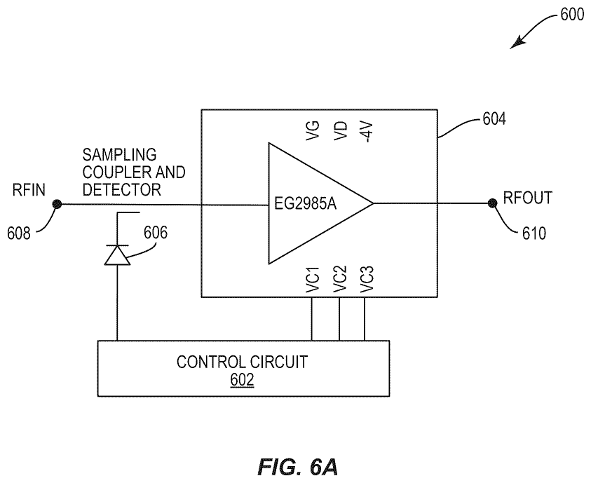

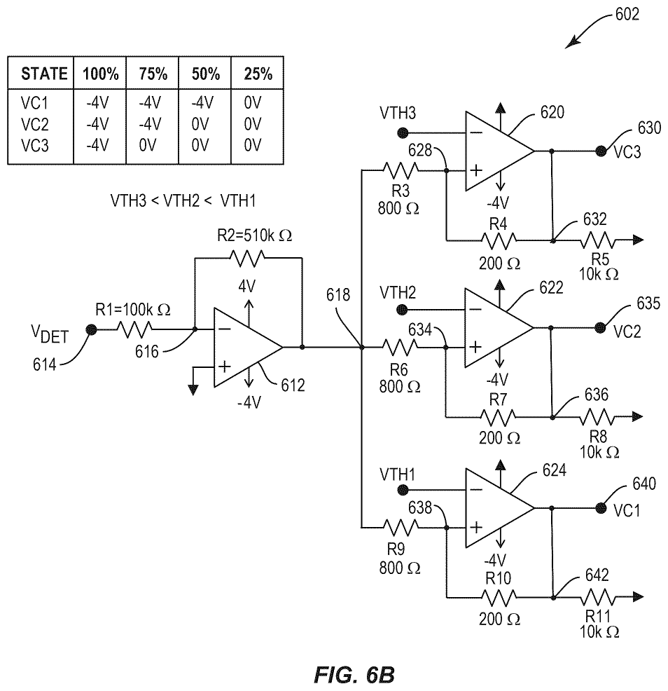

FIG. 6A and FIG. 6B illustrate a reconfigurable power amplifier 600 along with additional details regarding a control circuit 602 included in the reconfigurable power amplifier 600, in accordance with some embodiments.

In some embodiments, the reconfigurable power amplifier 600 is the reconfigurable power amplifier 200 or the reconfigurable power amplifier 300.

FIG. 6A illustrates that the couplers and amplifiers of the reconfigurable power amplifier 600 are formed by an integrated circuit package 604. In some embodiments, the reconfigurable power amplifier 600 is formed by a monolithic microwave integrated circuit. The control circuit 602 is provided, which is configured to activate and deactivate the amplifiers in accordance with a deactivation plan and place the different reconfigurable quadrature couplers in the through mode, the coupled mode, or the quadrature mode depending on the particular power mode that the reconfigurable power amplifier 600 is to operate in.

The control circuit 602 includes a sampling coupler and detector 606. In this manner, the control circuit 602 is configured to measure the input power at a main input port 608. In alternative embodiments, the sampling coupler and detector 606 is configured to measure the output power at a main output port 610. The control circuit 602 is configured to switch the reconfigurable power amplifier 600 into different power modes depending on the input power level of an input signal a₁ the main input port 608.

FIG. 6B illustrates one embodiment of the control circuit 602 shown in FIG. 6A.

The bias circuit 307 shown in FIG. 3A takes the levels of the voltages VC generated by the control circuit 602 and level shifts and directs the voltages to bias the gate voltages to turn the appropriate power amplifiers on and off. The control circuit 602 is configured to determine the values of the voltages VC in FIG. 2 in accordance to the deactivation plan shown in the table in FIG. 6B. The control circuit 602 shown in FIG. 6B assumed that the reconfigurable power amplifier 600 shown in FIG. 6A has four identical power amplifiers and the control circuit 602 sequentially turns off one power amplifier after another to sequence through the various power levels. The table in FIG. 6B accomplished this where the power levels achieved by the reconfigurable power amplifier 600 are approximately 1 W, 0.75 W, 0.5 W, and 0.25 W, in accordance with some embodiments.

The control circuit 602 includes an operational amplifier 612 that is configured to receive an input voltage V_{DET} at an inverted terminal and is configured to receive a ground volage at a non-inverted terminal. One power terminal of the operational amplifier 612 is configured to receive a voltage of +4V and the other power terminal of the operational amplifier 612 is configured to receive a voltage of −4V. The input voltage V_{DET} is received at an input terminal 614. A resistor R1 is connected in series between the input terminal 614 and a feedback node 616. In this embodiment, the resistor R1 has a resistance of 100 kΩ. A feedback loop is connected between an output terminal of the operational amplifier 612 and the feedback node 616. A resistor R2 is connected in series in the feedback loop. In this embodiment, the resistor R2 has a resistance of 510 kΩ.

The output terminal of the operational amplifier 612 is connected to a branch node 618 that splits into three branches. Three different operational amplifiers 620, 622, 624 are connected to a different one of the branches. A resistor R3 is connected in series between the branch node 618 and a feedback node 628. The feedback node 628 is connected to a non-inverted terminal of the operational amplifier 620. The inverting terminal of the operational amplifier 620 is configured to receive a threshold voltage VTH3. One power terminal of the operational amplifier 620 is configured to receive a voltage of 0V and the other power terminal of the operational amplifier 620 is configured to receive a voltage of −4V. An output terminal of the operational amplifier 620 is configured to generate a control voltage VC3 and output the control voltage VC3 from an output terminal 630. A feedback loop is formed that includes a T-node 632. A resistor R4 is connected in series between the T-node 632 and the feedback node 628. The resistor R4 has a resistance of 200 kΩ. The T-node 632 is connected directly to the output terminal 630 of the operational amplifier 620. Another resistor R5 is connected in series to the T-node 632. The resistor R5 has a resistance of 10 kQ.

A resistor R6 is connected in series between the branch node 618 and a feedback node 634. The feedback node 634 is connected to a non-inverted terminal of the operational amplifier 622. The inverting terminal of the operational amplifier 622 is configured to receive a threshold voltage VTH2. The voltage level of the threshold voltage VTH2 is less than the voltage level of the threshold voltage VTH3. One power terminal of the operational amplifier 622 is configured to receive a voltage of 0V and the other power terminal of the operational amplifier 622 is configured to receive a voltage of −4V. An output terminal of the operational amplifier 622 is configured to generate a control voltage VC2 and output the control voltage VC2 from an output terminal 635. A feedback loop is formed that includes a T-node 636. A resistor R7 is connected in series between the T-node 636 and the feedback node 634. The resistor R7 has a resistance of 200 kΩ. The T-node 636 is connected directly to the output terminal 635 of the operational amplifier 622. Another resistor R8 is connected in series to the T-node 636. The resistor R8 has a resistance of 10 kQ.

A resistor R9 is connected in series between the branch node 618 and a feedback node 638. The feedback node 638 is connected to a non-inverted terminal of the operational amplifier 624. The inverting terminal of the operational amplifier 624 is configured to receive a threshold voltage VTH1. The voltage level of the threshold voltage VTH1 is less than the voltage level of the threshold voltage VTH2. One power terminal of the operational amplifier 624 is configured to receive a voltage of 0V and the other power terminal of the operational amplifier 624 is configured to receive a voltage of −4V. An output terminal of the operational amplifier 624 is configured to generate a control voltage VC1 and output the control voltage VC1 from an output terminal 640. A feedback loop is formed that includes a T-node 642. A resistor R10 is connected in series between the T-node 642 and the feedback node 638. The resistor R10 has a resistance of 200 kΩ. The T-node 642 is connected directly to the output terminal 640 of the operational amplifier 624. Another resistor R11 is connected in series to the T-node 642. The resistor R11 has a resistance of 10 kQ.

The control circuit 602 is configured to generate the control voltages VC₁, VC₂, VC₃ in accordance with the bottom table of the deactivation plan shown in the table illustrated in FIG. 6B. The feedback loops ensure that each of the operational amplifiers 620, 622, 624 operate in hysteresis. Thus, each of the operational amplifiers 620, 622, 624 is configured to generate their respective control voltage VC₁, VC₂, VC₃ at a voltage level of either 0V or −4V.

The detector used in the test was a positive polarity detector, meaning that the output is near 0V at very low power and becomes more positive as the RF power is increased. At a low input power level, the input voltage is lower in magnitude than the threshold voltages VTH3, VTH2, VTH1. For example, VTH1=−0.8V, VTH2=−1.2V and VTH3=−1.6V would be a valid setting satisfying VTH3<VTH2<VTH1. The operational amplifier 612 is configured as an inverting amplifier with output range between −4V and 4V. Since the detector is positive polarity, the voltage at node 618 will be near 0V at very low RF power and become more negative (inverted) as power increases (increasing negative magnitude). At low RF power, the node 618 is at approximately 0V exists, which provides an input to the non-inverting terminals of the operational amplifiers 620, 622, and 624. It should be noted that other settings of the threshold voltages may be used depending on the application. In response, all three operational amplifiers 620, 622, 624 output each of the control voltages VC₁, VC₂, VC₃ at 0V. Accordingly, the reconfigurable power amplifier 600 is configured to operate in the power mode corresponding to the lowest power level Pₘₐₓ−Δ₁-Δ₂-Δ₃. Since all three thresholds VTH3, VTH2, VTH1 are negative, the outputs VC₁, VC₂, VC₃ will be equal to the positive supply rail, which in this case is 0V, realizing the 25% power state shown in the table of FIG. 6B.

As the RF power of the RF input signal increases, the input voltage V_{DET} applied to the non-inverting inputs of the operational amplifiers 620, 622, 624 becomes more negative until it is less (i.e., has a greater negative magnitude) than the threshold voltage VTH1 and the operational amplifier 624 that is configured to generate the control voltage VC₁ will transition from 0V to −4V while the control voltages VC₂, VC₃ remain at 0V. Accordingly, the reconfigurable power amplifier 600 is configured to operate in the power mode corresponding to the second lowest power level Pₘₐₓ-Δ1-Δ2. The 50% power state from the table in FIG. 6B is now active.

As the RF power of the RF input signal continues to increase, the input voltage V_{DET} applied to the non-inverting inputs of the operational amplifiers 620, 622, 624 becomes more negative until it is less (i.e., has a greater negative magnitude) than the threshold voltage VTH2 and the threshold voltage VTH1 and the operational amplifiers 622, 624 are configured to generate the control voltages VC2, VC1 at −4V while the control voltage VC3 remains at 0V. Accordingly, the reconfigurable power amplifier 600 shown in FIG. 3A is configured to operate in the power mode corresponding to the second highest power level Pₘₐₓ−Δ₁. The 75% power state from the table in FIG. 6B is now active.

As the RF power of the RF input signal further still increases, the input voltage V_{DET} applied to the non-inverting inputs of the operational amplifiers 620, 622, 624 becomes even more negative until it is less (i.e., greater in negative magnitude) than the threshold voltages VTH3, VTH2, VH1 and the operational amplifiers 622, 624 are configured to generate the control voltages VC3, VC2, VC1 at −4V. Accordingly, the reconfigurable power amplifier 600 shown in FIG. 3A is configured to operate in the power mode corresponding to the highest power level Pₘₐₓ.

Note that the input voltage V_{DET} being configured to detect power at the main input port 608 is simply exemplary. In alternate embodiments, the input voltage V_{DET} could measure the output signal a₁ the main output port 610.

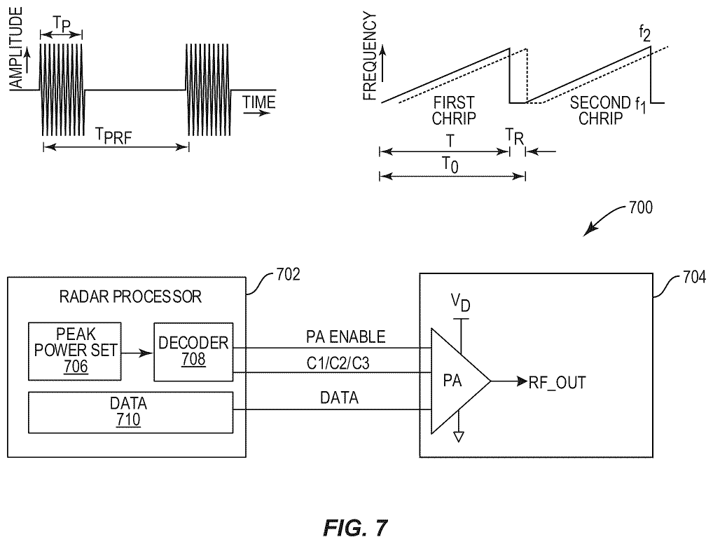

FIG. 7 illustrates a reconfigurable power amplifier 700 along with additional details regarding a control circuit 702 (also referred to as a radar processor 702) included in the reconfigurable power amplifier 700, in accordance with some embodiments.

In some embodiments, the reconfigurable power amplifier 700 is the reconfigurable power amplifier 200 of FIG. 2 or the reconfigurable power amplifier 300 of FIG. 3A.

FIG. 7 illustrates that the couplers and amplifiers of the reconfigurable power amplifier 700 are formed by an integrated circuit package 704. The couplers and amplifiers are configured to receive a power amplifier (PA) enable signal (PA Enable) that allows for the amplifiers to be activated, 2) the control voltages VC1, VC2, VC3, and 3) a data signal (Data). As shown in FIG. 7, the control circuit 702 is a radar processor that includes a peak power set circuit 706, a decoder 708 operably associated with the peak power set circuit 706, and a data circuit 710.

FIG. 7 illustrates that the concepts disclosed herein are applicable to a radar. In particular, pulsed and continuous wave (CW) radars are a popular choice for distance and velocity sensing of remote targets. Also, K-Ka band radars have wide use in commercial and military applications. For pulsed radar PA, a short pulse in the of width T_{P} seconds is emitted from the transmitter and repeated every T_{PRF} seconds, as shown in the upper left-hand graph of FIG. 7. Within a transmission window of the time T_{P}, a carrier wave can be at a single frequency, a swept frequency, a stepped frequency, or could be digitally encoded to improve radar range and/or resolution.

For various reasons including, but not limited to, power supply energy constraints, target near-far dynamic range control, target identification, signaling method, emissions requirements, and/or calibration, the pulsed radar PA will need to be backed off. Even for CW radars such as a Frequency Modulated CW radar, a reset time (TR) (as shown in the upper right-hand graph of FIG. 7) is incorporated to bring the radar transceiver back to its initialized state.

The output power of the reconfigurable power amplifier 700 is configured to be adjusted with the control voltages VC1, VC2, VC3 to operate in different power modes between successive transmissions in accordance with system requirements to maintain maximum PAE under backed-off power conditions. Depending on the radar waveform employed, the power mode of the reconfigurable power amplifier 700 is configured to be updated such that the reconfigurable power amplifier 700 is settled before the beginning of the next transmission. Similar to communication systems, the power management of the reconfigurable power amplifier 700 is simplified because a drain voltage VD is held constant since the power modes do not require adjusting the drain voltage VD to adjust the power output of the reconfigurable power amplifier 700.

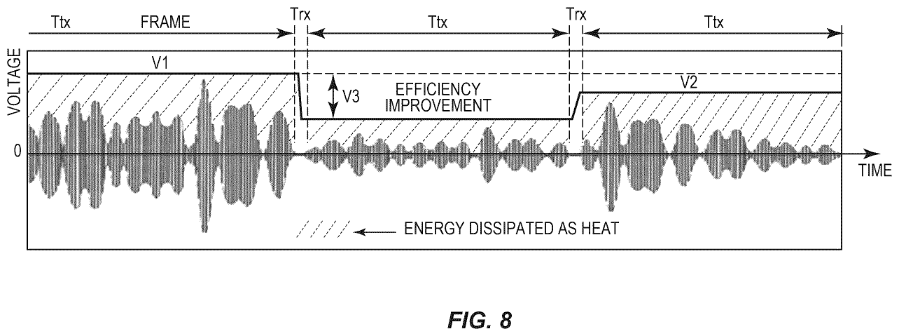

FIG. 8 illustrates average power tracking of frame-based signals, in accordance with some embodiments.

The reconfigurable power amplifier 700 shown in FIG. 7 can also be implemented to provide average power tracking of the frame-based signal shown in FIG. 8.

After encoding, the data, in bits, are grouped into consecutive signal blocks known as frames. Each frame generally contains a frame header and a synchronization waveform, enabling receivers to synchronize with incoming signal frames, process the headers, and decode the messages as indicated by the header information. The duration of each frame usually ranges from 10 to 100 milliseconds. The concept of average power tracking involves maintaining a constant power level while the reconfigurable power amplifier 700 transmits a single frame and allowing the power mode to be updated prior to the next frame. This is possible because the peak-to-average power ratio (PAPR) can be pre-computed based on a digital representation of the RF signal being transmitted.

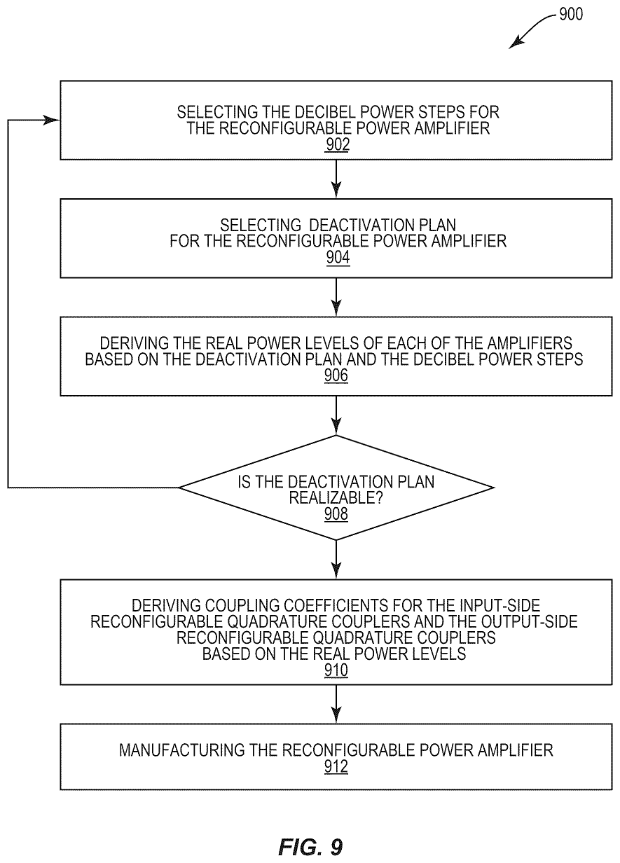

FIG. 9 is a flow diagram 900 of a method of designing a reconfigurable power amplifier, in accordance with some embodiments. In some embodiments, the reconfigurable power amplifier that is designed in accordance with this method described in FIG. 9 is the reconfigurable power amplifier 200 in FIG. 2 or the reconfigurable power amplifier 300 in FIG. 3A. The flow diagram 900 includes blocks 902-912. Flow begins at block 902.

At block 902, the decibel power steps for the reconfigurable power amplifier are selected. An example of the decibel power steps are Δ₁, Δ₂, Δ₃, as described above with respect to the explanation of FIG. 3A and FIG. 3B. Flow then proceeds to block 904.

At block 904, a deactivation plan is selected for the reconfigurable power amplifier. An example of the deactivation plan is the deactivation plan described in the tables shown in FIG. 3B. Flow then proceeds to block 906.

At block 906, the real power levels of each of the amplifiers is derived based on the deactivation level and the decibel power steps. An example of the real power levels are the power levels, in watts, of the power amplifiers PA₁, PA₂, PA₃, PA₄, as discussed above with respect to FIG. 3A and FIG. 3B. The specific example provided above provides the real power levels at the P_{1dB}. In other implementations, the real power levels may be calculated at a 2 dB compression point. Flow then proceeds to block 908.

At block 908, it is determined whether the deactivation plan is realizable. For example, if the deactivation plan results in the real power level of one of the power amplifiers PA₁, PA₂, PA₃, PA₄ being negative, then the deactivation plan is not realizable and another deactivation plan must be selected again at block 902. Otherwise, if the deactivation plan is realizable, then flow proceeds to block 910.

At block 910, coupling coefficients for the input-side reconfigurable quadrature couplers and the output-side reconfigurable quadrature couplers are derived based on the real power levels. Examples of the input-side reconfigurable quadrature couplers are the input-side reconfigurable quadrature couplers 202 in FIG. 2 and the input-side reconfigurable quadrature couplers 304 in FIG. 3A. Examples of the output-side reconfigurable quadrature couplers are the output-side reconfigurable quadrature couplers 208 in FIG. 2 and the output-side reconfigurable quadrature couplers 306 in FIG. 3A. An example of the coupling coefficients are β_{C1} (dB), α_{C1}⁻¹ (dB), β_{C2} (dB), α_{C2}⁻¹ (dB), β_{C3} (dB), α_{C3}⁻¹ (dB), α_{C1} (dB), β_{C1}⁻¹ (dB), α_{C2} (dB), β_{C2-1} (dB), α_{C3} (dB), β_{C3}⁻¹ (dB), as described in the derivation above with respect to FIG. 3A and FIG. 3B. Flow then proceeds to block 912.

At block 912, the reconfigurable power amplifier is manufactured in accordance with the deactivation plan, the real power values, and the coupling coefficient parameters derived in blocks 902-910. Power amplifiers and quadrature couplers are typically manufactured using specialized techniques in the microwave and RF industry. Power amplifiers are generally fabricated on semiconductor substrates like silicon (Si), gallium arsenide (GaAs), or gallium nitride (GaN) using processes like metal-organic chemical vapor deposition (MOCVD). The amplifier circuits are created through photolithography and etching techniques to form the transistors, resistors, capacitors, and other components. Careful attention is paid to thermal management and impedance matching. Quadrature couplers can be manufactured using several methods depending on the frequency and power requirements. At lower frequencies, they may use discrete components like capacitors and inductors. For higher frequencies, they are often made using microstrip or strip line techniques on printed circuit board (PCB) substrates. Details regarding the components involved in the reconfigurable quadrature couplers can be found in U.S. Pat. No. 11,539,108 B1 and U.S. Pat. No. 12,040,759 B2, both of which are incorporated herein in their entirety. Some designs use multilayer structures or specialized materials like low-temperature co-fired ceramic (LTCC). Waveguide versions for very high frequencies may be machined from metal. Both power amplifiers and quadrature couplers undergo testing and tuning to meet specifications for gain, efficiency, isolation, phase, and other key parameters. Advanced manufacturing controls and specialized RF test equipment may be used to ensure consistent performance across production runs.

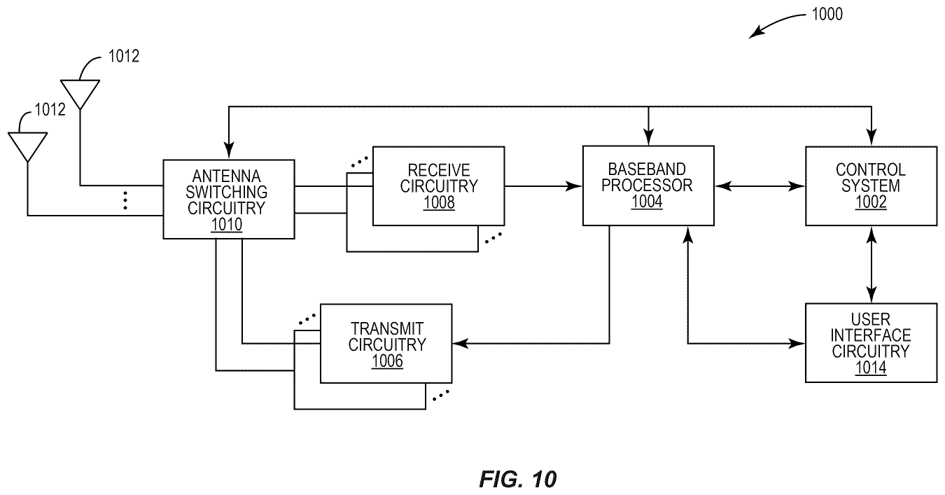

With reference to FIG. 10, the concepts described above may be implemented in various types of user elements 1000, such as mobile terminals, smart watches, tablets, computers, navigation devices, access points, and like wireless communication devices that support wireless communications, such as cellular, wireless local area network (WLAN), Bluetooth, and near field communications. The user element 1000 will generally include a control system 1002, a baseband processor 1004, transmit circuitry 1006, receive circuitry 1008, antenna switching circuitry 1010, multiple antennas 1012, and user interface circuitry 1014. In a non-limiting example, the control system 1002 may be a field-programmable gate array (FPGA) or an application-specific integrated circuit (ASIC). In this regard, the control system 1002 may include at least a microprocessor(s), an embedded memory circuit(s), and a communication bus interface(s). The receive circuitry 1008 receives radio frequency signals via the antennas 1012 and through the antenna switching circuitry 1010 from one or more base stations. A low noise amplifier and a filter cooperate to amplify and remove broadband interference from the received signal for processing. Down conversion and digitization circuitry (not shown) will then down convert the filtered, received signal to an intermediate or baseband frequency signal, which is then digitized into one or more digital streams using analog-to-digital converter(s) (ADC).

The baseband processor 1004 processes the digitized received signal to extract the information or data bits conveyed in the received signal. This processing typically comprises demodulation, decoding, and error correction operations, as will be discussed in greater detail below. The baseband processor 1004 is generally implemented in one or more digital signal processors (DSPs) and application specific integrated circuits (ASICs).

For transmission, the baseband processor 1004 receives digitized data, which may represent voice, data, or control information, from the control system 1002, which it encodes for transmission. The encoded data is output to the transmit circuitry 1006, where a digital-to-analog converter(s) (DAC) converts the digitally encoded data into an analog signal and a modulator modulates the analog signal onto a carrier signal that is at a desired transmit frequency or frequencies. A power amplifier (e.g., the reconfigurable power amplifier 200 in FIG. 2 or the reconfigurable power amplifier 300 in FIG. 3A) will amplify the modulated carrier signal to a level appropriate for transmission and deliver the modulated carrier signal to the antennas 1012 through the antenna.

Those skilled in the art will recognize improvements and modifications to the preferred embodiments of the present disclosure. All such improvements and modifications are considered within the scope of the concepts disclosed herein and the claims that follow.

What is claimed is:

1. A reconfigurable power amplifier, comprising:
a first amplifier having a first amplifier input terminal and a first amplifier output terminal;
a second amplifier having a second amplifier input terminal and a second amplifier output terminal;
a first input-side reconfigurable quadrature coupler coupled to the first amplifier input terminal and the second amplifier input terminal, wherein the first input-side reconfigurable quadrature coupler has unequal coupling coefficients; and
a first output-side reconfigurable quadrature coupler coupled to the second amplifier input terminal and the second amplifier output terminal, the first output-side reconfigurable quadrature coupler having an inverted configuration with respect to the first input-side reconfigurable quadrature coupler.

2. The reconfigurable power amplifier of claim 1, wherein:
the first input-side reconfigurable quadrature coupler comprises a first signal port, a first through port, a first coupled port, and a first isolated port;
the first through port is coupled to the first amplifier input terminal of the first amplifier;
the first coupled port is coupled to the second amplifier input terminal of the second amplifier;
the first input-side reconfigurable quadrature coupler comprises a first through port coupling coefficient between the first signal port and the first through port and a first coupled port coupling coefficient between the first signal port and the first coupled port; and
the first input-side reconfigurable quadrature coupler has the unequal coupling coefficients as a result of the first through port coupling coefficient and the first coupled port coupling coefficient being unequal.

3. The reconfigurable power amplifier of claim 2, wherein:
the first output-side reconfigurable quadrature coupler comprises a second signal port, a second through port, a second coupled port, and a second isolated port;
the first output-side reconfigurable quadrature coupler having a second through port coupling coefficient between the second signal port and the second through port and a second coupled port coupling coefficient between the second signal port and the second coupled port;
the first output-side reconfigurable quadrature coupler has the inverted configuration with respect to the first input-side reconfigurable quadrature coupler by:
the second through port being coupled to the second amplifier output terminal of the second amplifier;
the second coupled port being coupled to the first amplifier output terminal of the first amplifier;
the second though port coupling coefficient of the first output-side reconfigurable quadrature coupler being substantially equal to the first coupled port coupling coefficient of the first input-side reconfigurable quadrature coupler; and
the second coupled port coupling coefficient of the first output-side reconfigurable quadrature coupler being substantially equal to the first through port coupling coefficient of the first input-side reconfigurable quadrature coupler.

4. The reconfigurable power amplifier of claim 1, further comprising:
a 2^{N}−1 number of input-side reconfigurable quadrature couplers including the first input-side reconfigurable quadrature, the 2^{N}−1 number of input-side reconfigurable quadrature couplers being connected in a first tree structure with the first input-side reconfigurable quadrature coupler being at a base of the first tree structure and a root of the first tree structure being one of the input-side reconfigurable quadrature couplers having a main input terminal;
a 2^{N}−1 number of output-side reconfigurable quadrature couplers including the first output-side reconfigurable quadrature, the 2^{N}−1 number of output-side reconfigurable quadrature couplers being connected in a second tree structure with the second output-side reconfigurable quadrature coupler being at a base of the second tree structure and a root of the second tree structure is one of the output-side reconfigurable quadrature couplers having a main output terminal;
a 2^{N} number of amplifiers including the first amplifier and the second amplifier, the 2^{N} number of amplifiers divided into amplifier pairs, each of the amplifier pairs having amplifier input terminals coupled to a different one of the 2^{N}−1 number of input-side reconfigurable quadrature couplers at the base of the first tree structure and having amplifier output terminals coupled to a different one of the 2^{N}−1 number of output-side reconfigurable quadrature couplers at the base of the second tree structure;
at least some of the 2^{N}−1 number of input-side reconfigurable quadrature couplers having the unequal coupling coefficients;
each of the 2^{N}−1 number of output-side reconfigurable quadrature couplers having the inverted configuration with respect to the first input-side reconfigurable quadrature coupler that has a position in the first tree structure that corresponds to a position of the first output-side reconfigurable quadrature coupler in the second tree structure; and
wherein N is an integer equal to 2 or greater.

5. The reconfigurable power amplifier of claim 4, wherein an amplifier of the 2^{N} number of amplifiers is set to a same gain when the amplifier is activated.

6. The reconfigurable power amplifier of claim 5, wherein each of the 2^{N}−1 number of input-side reconfigurable quadrature couplers are configurable in a through mode or a quadrature more and each of the 2^{N}−1 number of output-side reconfigurable quadrature couplers are reconfigurable to operate in a coupled mode or the quadrature mode.

7. The reconfigurable power amplifier of claim 6, further comprising a control circuit, wherein the control circuit is configured to:
operate in accordance with a deactivation plan having different activation states, wherein, in each activation state, different combinations of the 2^{N} number of amplifiers are activated and deactivated, wherein an inverted mode of the quadrature mode is the quadrature mode, an inverted mode of the coupled mode is the through mode, and an inverted mode of the through mode is the coupled mode;
in each activation state of the different activation states, setting each of the 2^{N}−1 number of input-side reconfigurable quadrature couplers in either the quadrature mode, the through mode, or the coupled mode; and
in each activation state of the different activation states, set each of the 2^{N}−1 number of output-side reconfigurable quadrature couplers in the inverted mode with respect to the 2^{N}−1 number of input-side reconfigurable quadrature coupler that has the position in the first tree structure that corresponds to the position of the 2^{N}−1 number of output-side reconfigurable quadrature couplers in the second tree structure.

8. The reconfigurable power amplifier of claim 7, wherein, in each of the different activation states, each of the 2^{N}−1 number of input-side reconfigurable quadrature couplers is set to either the quadrature mode, the through mode, or the coupled mode such that portions of an input signal received at the main input port are routed only to amplifiers of the 2^{N} number of amplifiers that are activated in one of the different activation states.

9. The reconfigurable power amplifier of claim 1, wherein the first amplifier and the second amplifier are set to a same gain when the first amplifier and the second amplifier are activated.

10. The reconfigurable power amplifier of claim 9, wherein the first input-side reconfigurable quadrature coupler and the first output-side reconfigurable quadrature coupler are reconfigurable to operate in a quadrature mode, a through mode, and a coupled mode.

11. A method of designing a reconfigurable power amplifier comprising pairs of amplifiers, input-side reconfigurable quadrature couplers in a first tree structure, and output-side reconfigurable quadrature couplers in a second tree structure, the method comprising:
selecting decibel power steps for the reconfigurable power amplifier;
selecting a deactivation plan for the reconfigurable power amplifier;
deriving the real power levels of each of the amplifiers based on the deactivation plan and the decibel power steps;
deriving coupling coefficients for the input-side reconfigurable quadrature couplers and the output-side reconfigurable quadrature couplers based on the real power levels.

12. The method of claim 11, wherein the real power levels are derived at a 1 decibel compression point.

13. The method of claim 11, wherein each amplifier of the amplifiers are designed to be set to a same gain when the amplifier is activated.

14. A user element comprising a reconfigurable power amplifier, the reconfigurable power amplifier comprising:
a first amplifier having a first amplifier input terminal and a first amplifier output terminal;
a second amplifier having a second amplifier input terminal and a second amplifier output terminal;
a first input-side reconfigurable quadrature coupler coupled to the first amplifier input terminal and the second amplifier input terminal, wherein the first input-side reconfigurable quadrature coupler has unequal coupling coefficients; and
a first output-side reconfigurable quadrature coupler coupled to the second amplifier input terminal and the second amplifier output terminal, the first output-side reconfigurable quadrature coupler having an inverted configuration with respect to the first input-side reconfigurable quadrature coupler.

15. The user element of claim 14, wherein:
the first output-side reconfigurable quadrature coupler comprises a second signal port, a second through port, a second coupled port, and a second isolated port;
the first output-side reconfigurable quadrature coupler having a second through port coupling coefficient between the second signal port and the second through port and a second coupled port coupling coefficient between the second signal port and the second coupled port;
the first output-side reconfigurable quadrature coupler has the inverted configuration with respect to the first input-side reconfigurable quadrature coupler by:
the second through port being coupled to the second amplifier output terminal of the second amplifier;
the second coupled port being coupled to the first amplifier output terminal of the first amplifier;
the second though port coupling coefficient of the first output-side reconfigurable quadrature coupler being substantially equal to the first coupled port coupling coefficient of the first input-side reconfigurable quadrature coupler; and
the second coupled port coupling coefficient of the first output-side reconfigurable quadrature coupler being substantially equal to the first through port coupling coefficient of the first input-side reconfigurable quadrature coupler.

16. The user element of claim 14, further comprising:
a 2^{N}−1 number of input-side reconfigurable quadrature couplers including the first input-side reconfigurable quadrature coupler, the 2^{N}−1 number of input-side reconfigurable quadrature couplers being connected in a first tree structure with the first input-side reconfigurable quadrature coupler being at a base of the first tree structure and a root of the first tree structure being one of the 2^{N}−1 number of input-side reconfigurable quadrature couplers having a main input terminal;
a 2^{N}−1 number of output-side reconfigurable quadrature couplers including the first output-side reconfigurable quadrature coupler, the 2^{N}−1 number of output-side reconfigurable quadrature couplers being connected in a second tree structure with the second output-side reconfigurable quadrature coupler being at a base of the second tree structure and a root of the second tree structure being one of the 2^{N}−1 number of output-side reconfigurable quadrature couplers having a main output terminal;
a 2^{N} number of amplifiers including the first amplifier and the second amplifier, the 2^{N} number of amplifiers divided into amplifier pairs, each of the amplifier pairs having amplifier input terminals coupled to a different one of the 2^{N}−1 number of input-side reconfigurable quadrature couplers at the base of the first tree structure and having amplifier output terminals coupled to a different one of the 2^{N}−1 number of output-side reconfigurable quadrature couplers at the base of the second tree structure;
at least some of the 2^{N}−1 number of input-side reconfigurable quadrature couplers having the unequal coupling coefficients;
each of the 2^{N}−1 number of output-side reconfigurable quadrature couplers having the inverted configuration with respect to the input-side reconfigurable quadrature coupler that has a position in the first tree structure that corresponds to a position of the output-side quadrature coupler in the second tree structure;
wherein N is and integer equal to 2 or greater.

17. The user element of claim 16, wherein each amplifier of the 2^{N} number of amplifiers is set to a same gain when the amplifier is activated.

18. The user element of claim 17, wherein each of the 2^{N}−1 number of input-side reconfigurable quadrature couplers are each configurable in a through mode or a quadrature mode and each of the 2^{N}−1 number of output-side reconfigurable quadrature couplers are reconfigurable to operate in a coupled mode or the quadrature mode.

19. The user element of claim 18, further comprising a control circuit, wherein the control circuit is configured to:
operate in accordance with a deactivation plan having different activation states, wherein, in each activation state, different combinations of the 2^{N} number of amplifiers are activated and deactivated, wherein an inverted mode of the quadrature mode is the quadrature mode, an inverted mode of the coupled mode is the through mode, and an inverted mode of the through mode is the coupled mode;
in each activation state of the different activation states, setting each of the 2^{N}−1 number of input-side reconfigurable quadrature couplers in either the quadrature mode, the through mode, or the coupled mode; and
in each activation state of the different activation states, set each of the 2^{N}−1 number of output-side reconfigurable quadrature couplers in the inverted mode with respect to the 2^{N}−1 number of input-side reconfigurable quadrature couplers that has the position in the first tree structure that corresponds to the position of the 2^{N}−1 number of output-side reconfigurable quadrature couplers in the second tree structure.

20. The user element of claim 19, wherein, in each of the different activation states, each of the 2^{N}−1 number of input-side reconfigurable quadrature couplers is set to either the quadrature mode or the through mode such that portions of an input signal received at the main input port are routed only to the amplifiers that are activated in an activation state.
